(19) United States
(12) Patent Application Publication
(10) Pub. No.: US 2008/0165468 A1
(43) Pub. Date: Jul. 10, 2008

(54) VERY LOW PROFILE MULTILAYER COMPONENTS

(75) Inventors: Marianne Berolini, Southport, NC (US); John L. Galvagni, Surfside Beach, SC (US); Andrew P. Ritter, Surfside Beach, SC (US)

Correspondence Address: DORITY & MANNING, P.A., POST OFFICE BOX 1449, GREENVILLE, SC, 29602-1449, US

(73) Assignee: AVX Corporation, Myrtle Beach, SC (US)

(21) Appl. No.: 11/958,700

(22) Filed: Dec. 18, 2007

Related U.S. Application Data
(60) Provisional application No. 60/878,963, filed on Jan. 5, 2007.
(60) Provisional application No. 60/937,474, filed on Jun. 28, 2007.
(60) Provisional application No. 60/994,353, filed on Sep. 19, 2007.

(51) Int. Cl. H01G 4/005; H05K 1/16

(52) U.S. Cl. 361/306.3; 29/846; 361/766

(57) ABSTRACT

Methodologies are disclosed for producing multilayer electronic devices using a single screen printing mask. Plural layer devices are constructed by placing a common mask in alternating positions among alternating layers of support material such that, upon stacking of the plural layers, complimentary electrode structure is produced in alternating layers. Support material may be varied to produce different devices, including capacitors, resistors, and varistors. Multilayer electronic devices include multiple layers providing adjacent printed complimentary electrode layers having an upper surface, a lower surface, a front edge, and a back edge, and with lateral end portions of combined first and second layers trimmed so as to expose selected conductive patterns. Termination material is applied to at least such trimmed lateral end portions. A low inductance controlled equivalent series resistance (ESR) multilayer capacitor, includes at least two different pairs of electrodes, some of which have interdigitated respective side tabs. Termination material may be associated with such electrodes. In some instances, some electrodes may have dummy or anchor tabs associated with them but not electrically connected with them, to facilitate the formation of termination material at designated locations.

### PRIORITY CLAIM

This application claims priority under 35 U.S.C.119(e) of Provisional Patent Application Ser. No. 60/878,963 filed Jan. 5, 2007, entitled “Very Low Profile Multi-Layer Capacitor;” Provisional Patent Application Ser. No. 60/937,474 filed Jun. 28, 2007, entitled “Very Low Profile Multi-Layer Capacitor;” and Provisional Patent Application Ser. No. 60/994,353 filed Sep. 19, 2007, entitled “Low Inductance Thin Capacitors” all of which are hereby incorporated by reference in their entirety.

### FIELD OF THE INVENTION

The present subject matter generally concerns improved component formation for multilayer electronic components. More particularly, the present subject matter relates to methodologies for providing very thin capacitor structures suitable for use with smart card technology. The subject technology utilizes selective placement of a single electrode mask and specialized termination methodologies to fabricate very thin components.

### BACKGROUND OF THE INVENTION

Many modern electronic components are packaged as monolithic devices, and may comprise a single component or multiple components within a single chip package. One specific example of such a monolithic device is a multilayer capacitor or capacitor array, and of particular interest with respect to the disclosed technology are multilayer capacitors with interdigitated internal electrode layers and corresponding electrode tabs. Examples of multilayer capacitors that include features of interdigitated capacitor (IDC) technology can be found in U.S. Pat. Nos. 4,831,494 (Arnold et al), 5,880,925 (DuPré et al.) and 6,243,253 B1 (DuPré et al.). Other monolithic electronic components correspond to devices that integrate multiple passive components into a single chip structure. Such an integrated passive component may provide a selected combination of resistors, capacitors, inductors and/or other passive components that are formed in a multilayered configuration and packaged as a monolithic electronic device.

In known exemplary assembly methodologies, multilayer capacitors have been formed by providing individual sheets of a ceramic dielectric cut from a previously prepared extended length or tape of the ceramic material. The individual sheets are silk screen printed with electrode ink through multiple sets of electrode patterns. Printed sheets are then stacked in multiple layers and laminated into a solid layer often referred to as a pad. Further processing of multilayer capacitors constructed according to this known methodology included sintering of the pad and terminating of the individual components. Termination of the components includes application of a metal paint so as to come into contact with selected of the previously screen painted electrodes followed by another firing to secure the metal paint termination material to the capacitor.

The use of multiple sets of silk screen masks to produce differing alternate layers for multilayered devices represents a significant cost factor in the production of multilayered devices. Further, terminations commonly used with such multilayer devices consume a significant portion of the vertical height of the finished products.

Selective terminations are often required to form electrical connections for various monolithic layers. Multiple terminations may be needed to provide electrical connections to different internal electronic components of an integrated monolithic device. Multiple terminations are also often used in conjunction with IDC's and other multilayer arrays in order to reduce undesirable inductance levels. One exemplary way that multiple terminations have been formed in multilayer components is by drilling vias through selected areas of a chip structure and filling the vias with conductive material such that an electrical connection is formed among selected electrode portions of the device.

Alternate methodologies for forming external terminations for multilayer devices is to apply a thick film stripe of silver or copper in a glass matrix to exposed portions of internal electrode layers, curing or firing that material, and subsequently plating additional layers of metal over the termination stripes such that a part is solderable to a substrate. An example of an electronic component with external electrodes formed by fired terminations and metal films plated thereon is disclosed in U.S. Pat. No. 5,021,921 (Sano et al.). The application of terminations is often hard to control and can become problematic with reduction in chip sizes or with close features. U.S. Pat. Nos. 6,232,144 B1 (McLoughlin) and 6,214,685 B1 (Clinton et al) concern methods for forming terminations on selected regions of an electronic device.

The ever-shrinking size of electronic components makes it quite difficult to print termination stripes in a predetermined area with required precision. Thick film termination stripes are typically applied with a machine that grabs a chip and applies a pattern of terminations with specially designed wheels. U.S. Pat. Nos. 5,944,897 (Braden), 5,863,331 (Braden et al.), 5,753,299 (Garcia et al.), and 5,226,382 (Braden) disclose mechanical features and steps related to the application of termination stripes to a chip structure. Ever smaller spacing brought on by reduced component size or an increased number of termination contacts for an electronic chip device may cause the resolution limits of typical termination machines to become a limiting factor to further reductions.

Other problems that can arise when trying to apply patterned terminations with thick film processes include shifting of the termination lands, incorrect positioning of terminations such that internal electrode tabs are exposed or missed entirely, and missing wrap-around termination portions. Yet further problems may be caused when too thin a coating of the paint-like termination material is applied or when one portion of termination coating smears into another causing shorted termination lands. Another problem of the thick film systems is that it is often difficult to form termination portions on only selected sides of a device, such as on a vertical surface. These and other concerns surrounding the provision of electrical terminations for monolithic devices create a need to provide cheap and effective termination features for electronic chip components.

Yet another known option related to termination application involves aligning a plurality of individual substrate components to a shadow mask. Parts can be loaded into a particularly designed fixture, such as that disclosed in U.S. Pat. No. 4,919,076 (Lutz et al.), and then sputtered through a mask element. This is typically a very expensive manufacturing process, and thus other effective yet more cost efficient termination provisions may be desirable.

U.S. Pat. Nos. 5,880,011 (Zablotny et al.), 5,770,476 (Stone), 6,141,846 (Miki), and 3,258,898 (Garibotti), respectively deal with aspects of the formation of terminations for various electronic components.

Additional background references that address methodology for forming multilayer devices include U.S. Pat. Nos. 6,757,152 (Galvagni et al.), 4,811,164 (Ling et al.), 4,266,265 (Maher), 4,241,378 (Dorrian), and 3,988,498 (Maher).

While various aspects and alternative features are known in the field of multilayer electronic components and terminations thereof, no one design has emerged that generally addresses all of the issues as discussed herein. The disclosures of all the foregoing United States patents are for all purposes hereby fully incorporated into this application by reference thereto.

### BRIEF SUMMARY OF THE INVENTION

In view of the recognized features encountered in the prior art and addressed by the present subject matter, improved methodologies for producing multilayer electronic devices and associated aspects of electrical termination of such multilayer electronic devices, and resulting such devices, have been developed. Therefore, the present subject matter relates both to improved devices and apparatuses, and to corresponding related methodologies.

In exemplary configurations, multilayer devices may be produced using a single screen printing mask. According to certain aspects of the present subject matter, multilayer devices may be produced having differing electrical characteristics by selectively placing a single screen printing mask in alternative locations for alternate layers of a multilayer device.

According to additional aspects of certain embodiments of the present subject matter, multilayer device configurations may be produced resulting in either a single multilayer device or an effective series connected dual device being produced based exclusively on the amount of lateral shift applied to a single screen printing mask as successive layers are printed on selected support materials.

According to further aspects of certain embodiments of the present subject matter, multilayer device configurations may be produced using a single stationary screen followed by cutting and stacking individual successive layers.

According to yet other aspects of the present subject matter, termination methodologies have been developed that, in combination with the present single screen printing methodologies, produce a multilayer device of significantly less vertical height than previously possible.

In other present aspects of present exemplary embodiments, methodology is provided for making multilayer electronic devices, such methodology comprising the steps of: providing at least two layers of support material; providing a single screen printing mask; placing such mask on a first of the at least two layers of support material; printing a first conductive pattern on such first layer of the support material through the mask; placing such mask on a second of the at least two layers of support material; printing a second conductive pattern on the second layer of the support material; and combining the first and second layers of support material to produce adjacent printed layers having an upper surface, a lower surface, a front edge, and a back edge.

In variations of the foregoing exemplary embodiment, preferably such mask is placed on the second layer of support material in a position offset from the position on which the mask is placed on the first layer of support material and wherein, upon combining of the first and second layers, complimentary electrode layers are produced on adjacent layers of support material.

In alternatives and variations of the foregoing exemplary embodiments, preferably such step of providing at least two support layers comprises supplying one of at least two dielectric layers, at least two resistive layers, or at least two varistor layers.

In some of the foregoing embodiments, additional steps may be practiced for trimming lateral end portions of the stacked first and second layers to expose selected conductive patterns; and applying termination material to at least the trimmed lateral end portions. In various exemplary of such present methodologies, the step of applying termination material may further comprise applying termination material to at least a portion of selected electrodes exposed on at least one of the upper or lower surfaces of the combined first and second layers.

More generally, some examples of present exemplary methodology may further comprise the steps of: placing such mask on a third layer of support material; printing a third conductive pattern on such third layer of the support material; and combining such third layer on the first and second layers of support material. In such embodiments, the mask is placed on the third layer of support material in the same position as on the second layer of support material and wherein, upon combining of such third layer on the first and second layers, plural identical electrode layers are produced on adjacent layers of support material in proximity to one of the upper or lower surfaces.

Still further present exemplary embodiments may add to the foregoing, so that present methodologies for other embodiments further comprise the steps of: placing such mask on a third layer of support material; printing a third conductive pattern on such third layer of support material through the mask; placing such mask on a fourth layer of support material; printing a fourth conductive pattern on such fourth layer of the support material; placing such mask on a fifth layer of support material; printing a fifth conductive pattern on such fifth layer of the support material; and combining such third, fourth, and fifth layers on the first and second layers of support material one upon the other to produce a combination of printed layers having an upper surface and a lower surface; and trimming first and second lateral end portions of the combined layers to expose selected conductive patterns. With such exemplary arrangements, the mask is placed on the second and fourth layers of support material in a position offset from the position on which the mask is placed on the first, third, and fifth layers of support material and wherein, upon trimming of such combined layers, conductive electrode portions are exposed at selected layers and selected lateral end portions.

Whereas the preceding describes means to internally construct capacitors of low profile, it will be appreciated that the required termination also contributes to the overall thickness of the device. With the standard thick film terminations, such as described in U.S. Pat. No. 5,021,921 (Sano et al.), the termination may add 5 mils or more to the thickness. With expectations that the capacitor itself may typically be 9 mils thick or less, it can be appreciated that thick film terminations become significant drawbacks. Therefore, it is expected that the terminations described herein may best be thin film, which can be plated, as in U.S. Pat. Nos. 7,152,291 and 6,972,942 (Ritter et al.) or sputtered or evaporated as in U.S. Pat. No. 5,565,838 (Chan) with appropriate masking. Such terminations typically are less than a tenth of a mil of thickness. If the end cuts are made angular, then the technique described in U.S. Pat. No. 5,388,024 (Galvagni) can be used.

In still further present exemplary embodiments, methodology is disclosed for producing multilayer electronic devices using a single screen printing mask. More generally speaking, present plural layer devices may be constructed by placing a common mask in alternating positions among alternating layers of support material such that, upon stacking of the plural layers, complimentary electrode structure is produced in alternating layers. Support material may be varied to produce different devices including capacitors, resistors, and varistors.

Another present exemplary embodiment relates to a multilayer electronic device, comprising at least two layers of support material, with first and second conductive patterns. Preferably, such first conductive pattern is printed on the first layer of such support material, while a second conductive pattern is printed on the second layer of such support material. Further, preferably, such first and second layers of support material are combined so as to produce adjacent printed complimentary electrode layers having an upper surface, a lower surface, a front edge, and a back edge, and with lateral end portions of such combined first and second layers trimmed so as to expose selected conductive patterns. Additionally, preferably termination material is applied to at least such trimmed lateral end portions.

In variations and alterations of such exemplary embodiment, all in accordance with present subject matter, certain present embodiments of such device may have a minor dimension less than ten mils, while such termination material is less than one mil. In other present alternatives, in some embodiments, such termination material may be one of plated, sputtered, or evaporated onto such trimmed lateral end portions. In still further variations, in some present embodiments, such device may be less than 10 mils thick, and may have termination coverage on less than five sides thereof.

In another present exemplary embodiment, a low inductance controlled equivalent series resistance (ESR) multilayer capacitor is provided having at least first and second pairs of electrodes, and having a plurality of dummy tabs. Preferably, such at least first pair of electrodes may comprise interdigitated electrodes having a respective end tab on opposite ends thereof, to reduce inductance and resistance, and to provide for ease of testing during the manufacturing process. Still further, such first pair of electrodes may preferably have respective side tabs interdigitated with those of the other interdigitated electrode. Such at least second pair of electrodes preferably has a respective end tab on opposite ends thereof. Such dummy tabs preferably are formed adjacent such electrodes but not electrically connected thereto, to provide support and nucleation points for electroless copper termination.

In variations of the foregoing exemplary low inductance controlled ESR multilayer capacitor embodiment, a second set of such first pair of electrodes may be positioned at an upper end of such multilayer device, while the first set of such first pair are positioned at the lower or bottom end thereof, so as to create a symmetrical device for mounting purposes.

In yet another variation of the foregoing exemplary low inductance controlled ESR multilayer capacitor, additional second pairs of electrodes may be provided in stacked patterns, and termination material applied thereto so as to create a circuit of parallel connections of such second pairs of electrodes and series connections thereof with respective opposite ends of such first pair of electrodes. In certain of the foregoing exemplary embodiments, such termination material comprises electroless copper terminations.

Yet another present exemplary embodiment relates to a low inductance controlled equivalent series resistance (ESR) multilayer capacitor, comprising at least a first pair of electrodes comprising interdigitated electrodes having a respective end tab on opposite ends thereof, to reduce inductance and resistance, and to provide for ease of testing during the manufacturing process, and having respective side tabs interdigitated with those of the other interdigitated electrode, and at least a second pair of electrodes having a respective end tab on opposite ends thereof. Such exemplary embodiment preferably may further include termination material selectively interconnecting such electrodes.

Additional objects and advantages of the present subject matter are set forth in, or will be apparent to, those of ordinary skill in the art from the detailed description herein. Also, it should be further appreciated that modifications and variations to the specifically illustrated, referred and discussed features, elements, and steps hereof may be practiced in various embodiments and uses of the present subject matter without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the present subject matter may include various combinations or configurations of presently disclosed features, steps, or elements, or their equivalents (including combinations of features, parts, or steps or configurations thereof not expressly shown in the Figures or stated in the detailed description of such Figures). Additional embodiments of the present subject matter, not necessarily expressed in the summarized section, may include and incorporate various combinations of aspects of features, components, or steps referenced in the summarized objects above, and/or other features, components, or steps as otherwise discussed in this application.

Additionally it should be appreciated that, while the examples given herein relate primarily to structures and methodologies for the production of very thin capacitors where electrode layers are printed on support material corresponding to various dielectric materials, such is not limiting to the disclosure as the subject matter disclosed herein may also be applied to produce other very thin devices by providing alternate selections for the dielectric materials selected for use in the illustrated and discussed capacitor examples. As an example, a varistor or a resistor device may be produced using the methodologies of the present subject matter by selection of appropriate inter-electrode support materials. Those of ordinary skill in the art will better appreciate the features and aspects of such embodiments, and others, upon review of the remainder of the specification.

### BRIEF DESCRIPTION OF THE DRAWINGS

A full and enabling disclosure of the present subject matter, including the best mode thereof, directed to one of ordinary skill in the art, is set forth in the specification, which makes reference to the appended Figures, in which:

FIGS. 1a and 1b respectively display pictorially a first portion of sequential steps in the production of a first exemplary embodiment of an electronic device in accordance with the present subject matter, while FIG. 1c illustrates a perspective rendering of such subject matter, with partially transparent features;

FIGS. 2a-2d respectively illustrate sequentially a second portion of sequential steps in the production of a first exemplary embodiment of an electronic device in accordance with the present subject matter and include an alternative top layer electrode configuration, with present FIG. 2a′ representing in part yet a further present alternative arrangement;

FIGS. 3a and 3b respectively represent known configurations for comparison purposes in relation to the present subject matter, with FIG. 3c illustrating a partial side view of such known subject matter;

FIGS. 4a-4d respectively display pictorially sequential steps in the production of a second exemplary embodiment of an electronic device in accordance with the present subject matter;

FIGS. 5a-5e and 5g respectively display pictorially sequential steps in the production of third exemplary embodiment of electronic devices in accordance with the present subject matter and further illustrate the production of feedthrough and Pi filter devices;

FIGS. 5f and 5h represent electrical equivalent circuits of the devices illustrated in FIGS. 5e and 5g, respectively;

FIGS. 6a-6e and 6g respectively display pictorially sequential steps in the production of fourth exemplary embodiment of electronic devices in accordance with the present subject matter and further illustrate the production of feedthrough and Pi filter devices;

FIGS. 6f and 6h represent electrical equivalent circuits of the devices illustrated in FIGS. 6e and 6g, respectively;

FIGS. 7a-7e and 7g respectively display pictorially sequential steps in the production of fifth exemplary embodiment of electronic devices in accordance with the present subject matter and further illustrate the production of feedthrough and Pi filter devices;

FIGS. 7f and 7h represent electrical equivalent circuits of the devices illustrated in FIGS. 7e and 7g, respectively;

FIG. 8 illustrates an exemplary embodiment of the present subject matter employing end termination features;

FIGS. 9a-9c respectively illustrate a further exemplary embodiment of an electronic device in accordance with the present subject matter incorporating a “T” electrode and dummy tabs to assist in termination;

FIG. 9d illustrates a single screen pattern for producing electrode layers for the exemplary device illustrated in FIGS. 9a-9c;

FIGS. 10a-10c respectively illustrate additional exemplary embodiments of electronic devices in accordance with the present subject matter that provides improved mounting ability through 90° symmetry;

FIG. 11 illustrates a single screen pattern for producing electrode layers for the exemplary embodiment illustrated in FIG. 10c;

FIGS. 12a-12d respectively illustrate sequentially a further embodiment of present subject matter, illustrated in a manner analogous to FIGS. 2a-2d but with the aspect ratio thereof changed to permit attachment on the longer edge, so as to provide relatively lower inductance and stronger bonding;

FIGS. 13a-13e respectively represent alternative embodiments of the present technology wherein all layers are active, and wherein angular edges are provided to facilitate alternate attachment methodologies;

FIGS. 14a-14e respectively illustrate aspects of a further exemplary embodiment in accordance with the present technology wherein multiple components are formed together as an array for real estate saving and for part count reducing purposes;

FIGS. 15a-15f respectively illustrate representative views of a construction methodology in accordance with the present technology employing vias to provide a point contact or Ball Grid Array (BGA) format for external connections, reducing the ESL;

FIGS. 16a-16e respectively illustrate representative views of a thin-cap construction configured in a manner similar to a standard Multi-Layer Capacitor (MLC) with five sided terminations at each end;

FIGS. 17a-17e respectively illustrate steps in the construction of yet another embodiment of the present subject matter;

FIGS. 18a-18h respectively illustrate steps in constructing a low inductance capacitor using vias in accordance with the present technology;

FIGS. 19a-19c depict respective illustrations of a known configuration for providing a relatively low inductance part, using interdigitated electrodes to accomplish such low inductance, generally as described in U.S. Pat. Nos. 5,880,925 (DuPré et al.) and 6,243,253 B1 (DuPré et al.);

FIGS. 19d-19g depict respective illustrations of a technique for the application of anchor or dummy tabs to provide a substructure for electroless copper termination, generally as described in Ritter et al., U.S. Pat. No. 7,152,291; and

FIGS. 20a-20d illustrate a further present exemplary embodiment, incorporating both low inductance features and controlled equivalent series resistance (“ESR”) features.

Repeat use of reference characters throughout the present specification and appended drawings is intended to represent same or analogous features, elements, or steps of the present subject matter.

### DETAILED DESCRIPTION OF THE PREFERRED EMBODIMENTS

As discussed in the Summary of the Invention section, the present subject matter is particularly concerned with improved methodologies for producing multilayer electronic devices and associated aspects of electrical terminations, and resulting devices corresponding therewith. Selected combinations of aspects of the disclosed technology correspond to a plurality of different embodiments of the present subject matter. It should be noted that each of the exemplary embodiments presented and discussed herein should not insinuate limitations of the present subject matter. Features or steps illustrated or described as part of one embodiment may be used in combination with aspects of another embodiment to yield yet further embodiments. Additionally, certain features may be interchanged with similar devices or features not expressly mentioned which perform the same or similar function.

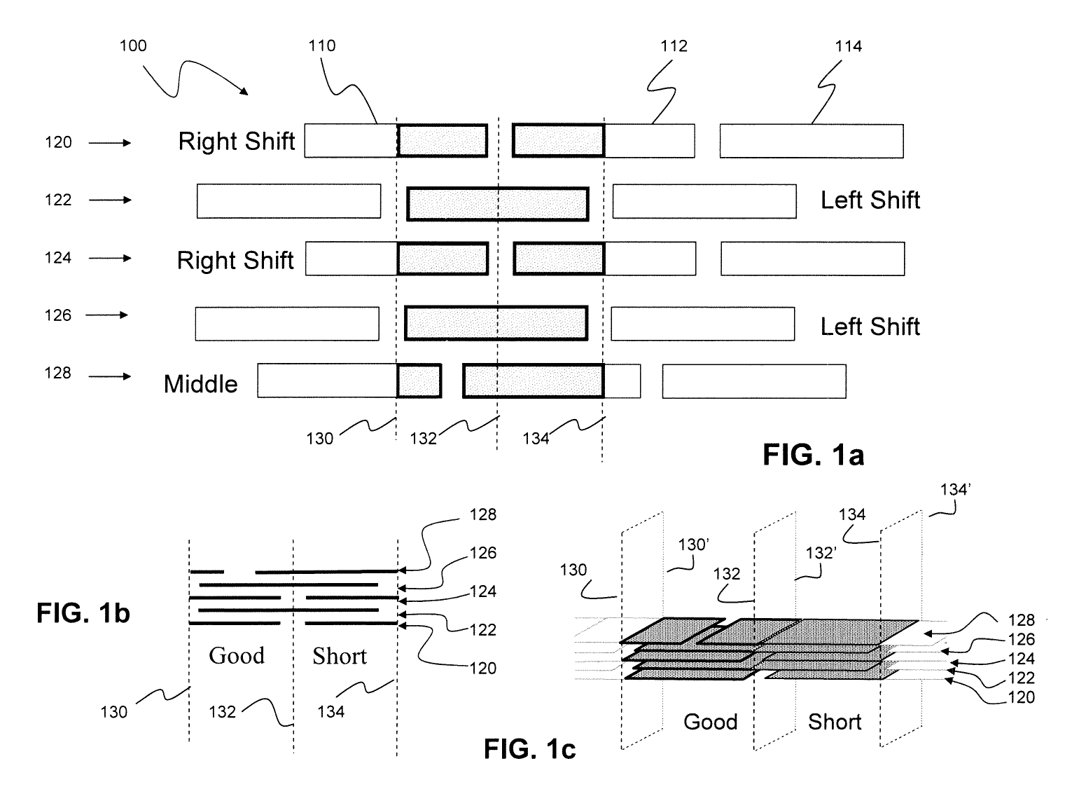

Reference will now be made in detail to the presently preferred embodiments of the subject multilayer device. Referring now to the drawings, FIGS. 1a and 1b illustrate a first portion of sequential steps that may be followed in the production of a first exemplary embodiment of an electronic device in accordance with the present subject matter, while FIG. 1c illustrates a perspective rendering of such subject matter, with partially transparent features. As shown in FIG. 1a, a first screen printing mask 100 includes three openings 110, 112, 114, each of the same length and width.

It should be noted that throughout the following descriptions of the various screen printing masks, portions of the masks have been illustrated as clear elements while other portions have been shaded. In both instances, the exemplary screens are open to allow passage of printing material, as is understood by those of ordinary skill in the screen printing arts. Where screens are illustrated as shaded, such is to draw particular attention to those areas as being areas that will representatively correspond to electrodes in a finished product.

With further reference to FIG. 1a, it will be noticed that there have been illustrated five successive layers 120-128, where five successive screen prints are to be made on five layers of inter-electrode support material, which is not illustrated in the Figures for simplicity. In the instance that the electronic devices being produced are capacitors, the layers on which electrodes may be printed by way of screen printing mask 100 may be a dielectric layer. As previously pointed out, alternative support materials may be selected if other devices including, but not limited to, resistors, thermistors, and varistors are to be produced.

Prior to screen printing a first layer 120 in the sequence of layers, the screen printing mask 100 is shifted a predetermined distance to the right as viewed from FIG. 1a, relative to a more central or middle position as illustrated at the fifth layer 128. After printing first layer 120, a layer of inter-electrode material is deposited and the screen printing mask 100 is shifted a predetermined distance to the left as viewed from FIG. 1a, relative to a more central or middle position as illustrated at the fifth layer 128. This shift and print process is repeated for the illustrated third layer 124 and fourth layer 126. Finally the screen printing mask 100 is positioned in a middle position as illustrated at layer 128 and a final printing is undertaken.

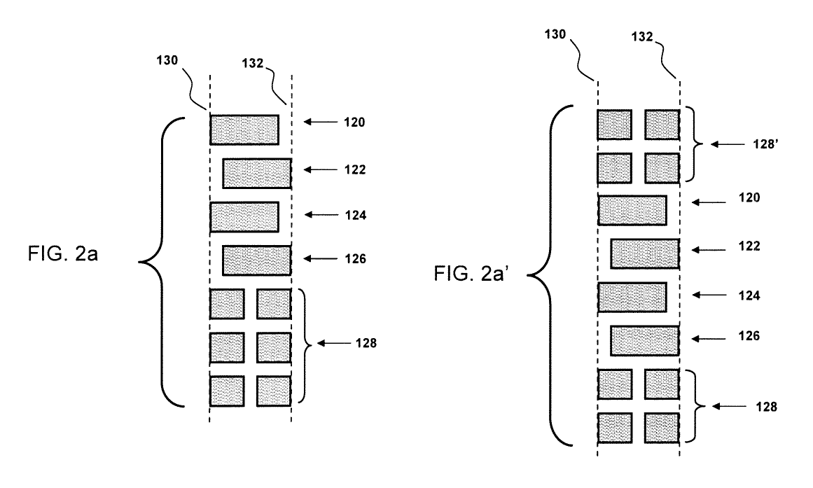

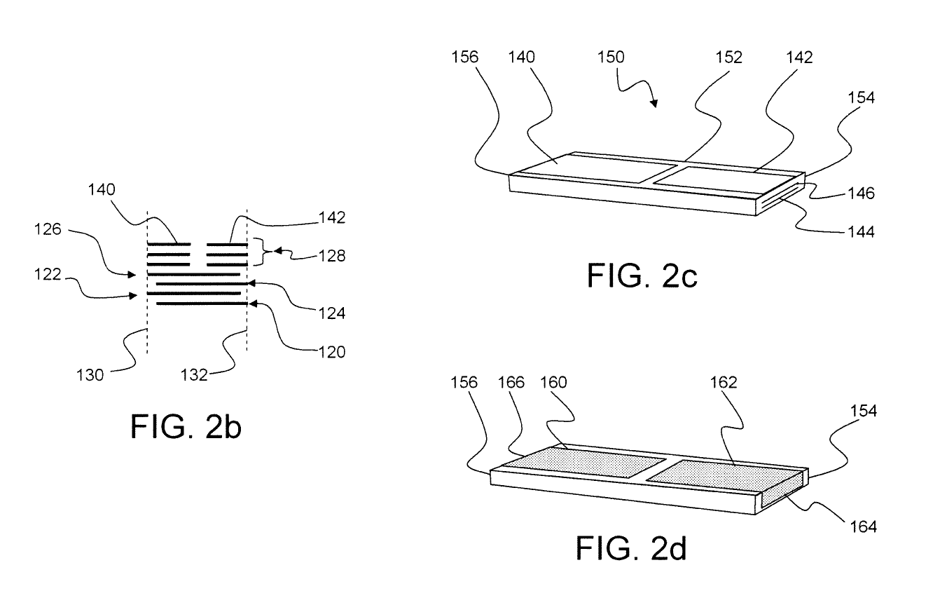

It should be clearly understood that the illustration herein of a total of five print layers is exemplary only. In actual production, more or fewer numbers of layers may be provided to produce a component meeting desired electrical and physical characteristics. Also, as will be seen with reference to FIGS. 2a and 2b, certain layers may be duplicated, that is reprinted, without shifting the screen printing mask 100 for reasons that will be discussed further below.

Referring collectively to FIGS. 1a, 1b, and 1c, it will be noticed that there are indicated a set of three cutting lines 130,132, and 134. After the selected number of layers of the multilayer device is printed (remembering that there may be more or less than the number illustrated), individual devices are cut from the stack of layers along cutting lines 130, 132, and 134. Such cutting, in the case of the devices illustrated in FIG. 1b, results in the production of two possible device types, one between cut lines 130 and 132 and another between cut lines 132 and 134. FIG. 1c shows the same features as illustrated in FIGS. 1a and 1b, except as a perspective rendering. The cut lines 130, 132, and 134 now become cutting planes, represented as 130-130′, 132-132′, and 134-134′, respectively.

One of the aspects of this particular embodiment of the present subject matter is that the process intentionally produces what may be considered a defective or “shorted” component if normal terminations are applied. Reviewing FIG. 1b, it will be understood that if terminations are applied to the ends of the electrodes exposed at cut lines 130 and 132, a good device will be produced because there is a gap between the electrode layers of the top layer 128. On the other hand, the top layer 128 of the device created between cut lines 132 and 134 is continuous. Placing terminations along the cut lines 132 and 134 at the exposed ends of the electrodes will result in a shorted product due to the continuous top layer 128.

This potentially negative aspect of this embodiment of the present technology is offset, however, on at least two levels. Firstly, the “good” elements (those between cut lines 130 and 132) can have a higher capacitive value in the instance that the present subject matter is being used to produce capacitors. Secondly, the savings in production of the devices based on the use of a single screen printing mask 100 offset the loss in product due to any such shorting effect. The sorting of the “good” versus “bad” parts can easily be done by high-speed electrical tests when the product is finished.

With reference now to FIGS. 2a-2d, there is sequentially illustrated a second portion of steps in the production of the first exemplary embodiment of an electronic device in accordance with the present subject matter. As previously mentioned, and illustrated particularly with reference to FIGS. 2a and 2b, top electrode layer 128 may optionally be provided as a plurality of layers. Three layers are exemplarily illustrated but is should be clearly understood that more or fewer numbers of layers may be provided.

Following printing of the various layers 120-128 as represented in FIGS. 2a and 2b, the cut devices are fired using processes well known to those of ordinary skill in the art. Such firing process results in a device 150 as illustrated in FIG. 2c. As illustrated in FIG. 2c, the top most layer of the possible plurality of layers 128 presents electrode portions 140, 142 on upper surface 152 of device 150, while the end portion 154 of the device 150 has exposed thereon the end portions of the right-end tenminated electrode layers 120 and 124 along with the dummy tabs 128, representatively illustrated as electrode ends 144, 146. It should be understood that, although not visible in the FIG. 2c illustration, similar electrode end portions of electrodes 122 and 126 along with their corresponding dummy tabs 128 will be exposed on opposite end 156 of device 150.

Following an initial firing, termination material 160, 162, 164, and 166 is applied to the exposed areas 140, 142 of the top layer 128 and contacts the remaining electrode ends for each respective layer 120 and 124 along the end portion 154 by way of termination portion 164. It should be understood that termination portions 162 and 164 continuously cover the top most electrode dummy layers 128, including their top portion 142 as well as the electrode portions exposed at end 154 of device 150. It should further be appreciated that similar coverage of exposed electrode ends 166 at end 156 of device 150 is provided although not visible in the current view of the device 150, thus unifying electrically the left dummy tabs 128 and the internal electrodes 122 and 126.

Finally, it should be recognized that the termination portions 160 and 162 will add to the thickness of the overall part, so thin film techniques such as plating, evaporation, sputtering, or organo-metallic reduction should preferably be used.

With reference to present FIG. 2a′, an additional alternative is shown, in part, to address differences that can otherwise occur in firing shrinkage dynamics. More specifically, it has been found that additional advantages are obtained against potential warping of a part (such as due to firing shrinkage dynamic differences) if the arrangement and design are balanced in the context as represented in present FIG. 2a′. As shown, the electrode layer 128 is repeated on the opposite side, per the indicated electrode layer 128′, for such desired balance. Other features for such an alternative and corresponding with the other aspects of FIGS. 2b, 2c, and 2d would be understood by one of ordinary skill in the art from the remaining disclosure herewith, without repetition of such figures directed specifically to all of the reference characters of present alternative FIG. 2a′.

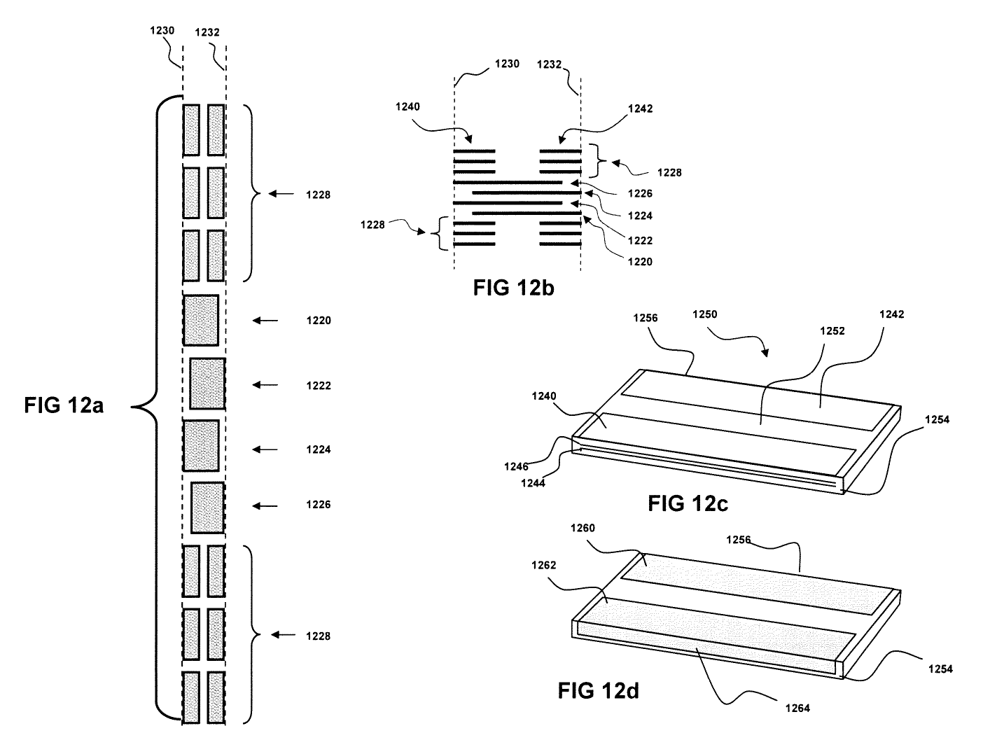

With reference now to FIGS. 12a-12d, there are presented sequential illustrations of respective steps in the production of another exemplary embodiment of an electronic device in accordance with the present subject matter. As may be seen from a respective comparison of the exemplary embodiments of the present technology as illustrated in FIGS. 2a-2d and 12a-12d, the embodiments generally represent a 90 degree shift in electrode alignment from each other. The electrode orientation illustrated in FIGS. 12a-12d provides a longer connection edge, resulting in relatively lower inductance, lower ESR, and a stronger physical and electrical connection for the device over that described with reference to FIG. 2a-2d. It should be appreciated that, in a similar manner to that mentioned with reference to FIGS. 2a and 2b, top electrode dummy layers 1228, together with their totally exposed parts 1240 and 1242 may optionally be adjusted in count as demanded by the application and the shrinkage dynamics. Three layers are illustrated by way of example only but is should be clearly understood that alternatively more or fewer numbers of layers may be provided, as selected by the user for implementation in a particular application, all of which variations are intended to be encompassed by the present disclosure. Further it should be understood that the count of the internal active electrodes 1220-1226 may be altered to effect particular electrical or physical requirements.

It should also be appreciated that, as the embodiment illustrated in FIGS. 12a-12d may be constructed using a single mask in a manner similar to that of the embodiment of FIGS. 2a-2d, both “good” and “bad” elements are produced so that only those elements cut along cut lines 1230, 1232 (like cut lines 130, 132 of the exemplary embodiment of FIG. 2a) produce “good” elements. It is to be understood that the terminology “good” versus “bad” elements as used herein is intended to refer to those portions of constructions which result in targeted elements for an intended ultimate construction or use, and not to otherwise indicate or reflect that there is anything inherently wrong about any portion or element referred to in such context as “bad.” The same advantages as ascribed to the embodiment of FIGS. 2a-2d relative to higher capacity and production savings are also enjoyed in the exemplary embodiment represented with FIGS. 12a-12d.

Following printing of the various layers 1220-1228 as represented in FIGS. 12a and 12b, the cut devices are fired using processes well known to those of ordinary skill in the art. Such firing processes result in a device 1250 as illustrated in FIG. 12c. As illustrated in FIG. 12c, the top most layer of the possible plurality of layers 1228 presents electrode portions 1240, 1242 on upper surface 1252 of device 1250, while the side portion 1254 and 1256 of the device 1250 have exposed thereon their respective end portions of all the electrode layers 1220-1228, representatively illustrated as electrode ends 1244, 1246. It should be understood that, although not visible in the FIG. 12c illustration, such FIG. 12c nonetheless represents that similar electrode end portions would be exposed on opposite end 1256 of device 1250.

Following an initial firing, termination materials 1260, 1262, and 1264 are applied as illustrated to the exposed areas 1240, 1242 of the top layer 1228 and contact the remaining electrode ends for each respective layer 1220-1226 and any internal dummy tabs 1228 along the side portion 1254 by way of termination portion 1264. It should be understood that termination portions 1262 and 1264 continuously cover portion 1242 of the top most electrode layer 1228 as well as the electrode portions exposed at end 1254 of device 1250. It should further be appreciated that similar coverage of exposed electrode ends at end 1256 of device 1250 is provided although not visible in the current view of the device 1250.

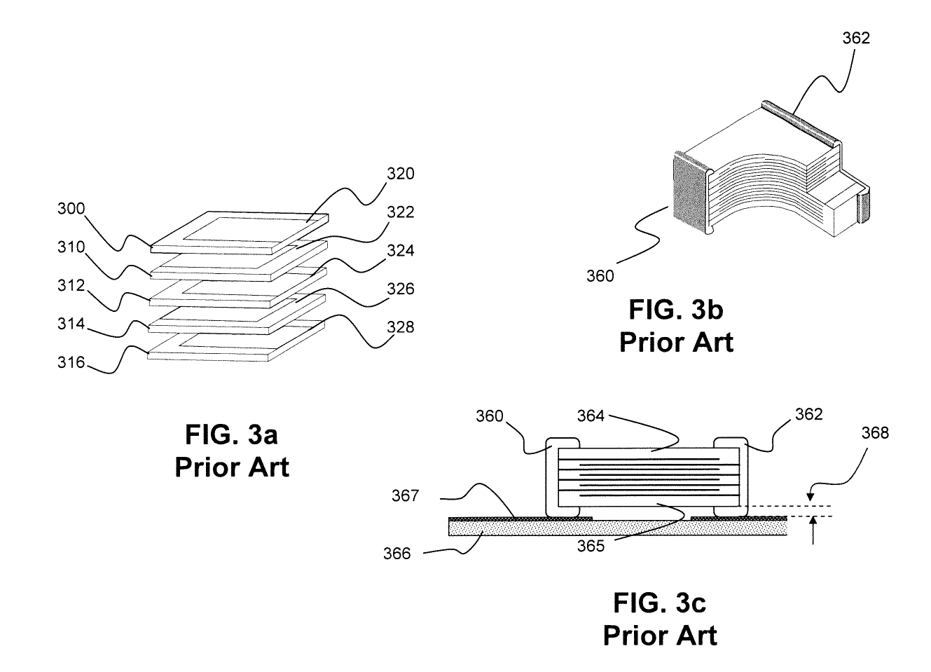

With collective reference to FIGS. 3a, 3b, and 3c, there is illustrated a known configuration for comparison purposes with the present subject matter. As illustrated in FIG. 3a, a plurality of ceramic layers 300, 310, 312, 314, and 316, are each respectively provided with individual electrode layers 320, 322, 324, 326, and 328. Alternating electrode layers are positioned along alternating side edges of the respective ceramic layers 300-316 such that when termination layers 360, 362 (FIG. 3b) are applied to the known device, alternate electrode layers are coupled together to produce a capacitor. In such known configuration, electrode layers are generally produced through the use of separated screen printing masks and, as more clearly illustrated in FIG. 3c, the upper most layer generally 364 and lower most layer generally 365 must be chosen to be a blank ceramic layer to avoid shorting the finished product. Such required inclusion of additional layers is a feature that is avoided in the present subject matter, thereby assisting in reducing the overall height of the finished product.

Present FIG. 3c illustrates another feature or aspect of such known configuration which should be appreciated by those of ordinary skill in the art. Specifically, because of the relatively thick termination paste used on prior art devices, respective terminations 360 and 362 of such exemplary known configuration add 2 to 3 mils to the product height on each surface, which results in 4 to 6 mils more of overall height, and 2 to 3 mils more clearance off the board 366 and its pads 367. Such clearance is represented by gap 368 as shown in FIG. 3c, and can lead to problems, not only with needless height, but with a location which can otherwise trap flux residues and cause electrical and environmental problems.

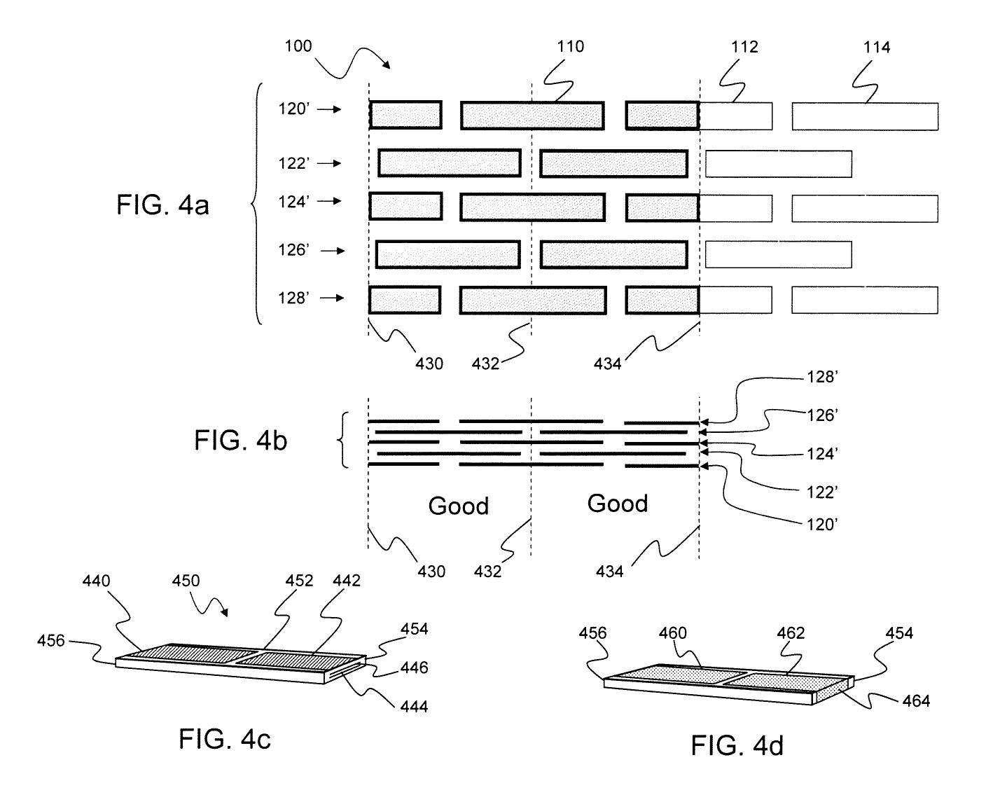

With reference to FIGS. 4a-4d, there are illustrated sequential steps in the production of a second exemplary embodiment of an electronic device in accordance with the present subject matter. The second exemplary embodiment of the present subject matter employs the identical screen printing mask 100 as used in the first exemplary embodiment of the present subject matter discussed with respect to FIGS. 1a and 1b. The difference with respect to the previous exemplary embodiment lies in the amount and type of mask shifting undertaken.

Such second exemplary embodiment of the present subject matter is constructed in a manner otherwise identical to that of the first embodiment with the exception of the type and amount of mask shifting, yet this technique results in device production that differs from the device of the first embodiment in two respects. Firstly, the devices produced take the form of a plurality of series coupled capacitors (in the instance that capacitors are being produced using the present subject matter). Secondly, unlike the first embodiment, all the devices produced are “good” from the standpoint that there is no shorting of produced devices due to placement of the top most electrode layer 128′.

With reference to FIG. 4a, it will be seen that a first electrode layer 120′ is printed on un-illustrated dielectric material with the screen printing mask 100 positioned in a central or middle location. The second electrode layer 122′ is printed after the screen printing mask 100 has been shifted to the left relative to the middle position of layer 120′. The next electrode layer 124′ is printed following return of the screen printing mask 100 to the same central or middle position it had occupied for the printing of layer 120′. Electrode layer 126′ is produced with a left shift of the screen printing mask 100 to the same position occupied by the mask for printing of electrode layer 122′. Finally screen printing mask 100 is repositioned to the same central or middle position it previously occupied for the printing of electrode layers 120′ and 124′ so that electrode layer 128′ may be printed. As with the first embodiment of the present subject matter, it should be kept in mind that the actually provided number of electrode layers may be more or fewer that that here exemplarily illustrated.

With further reference to FIGS. 4a and 4b, it will be observed that when the individual devices are produced by severing the various layers 120′-128′ along cut lines 430, 432, and 434 in a manner similar to that followed with respect to the first exemplary embodiment, the individual devices are all “good” from the standpoint that none of the devices are shorted based on positioning of the top layer 128′.

Following printing of the various layers 120′-128′ as represented in FIGS. 4a and 4b, the cut devices are fired using processes well known to those of ordinary skill in the art as previously discussed above. Such firing process results in a device 450 as illustrated in FIG. 4c. As illustrated in FIG. 4c, the top most layer of the possible plurality of layers 128′ (similar to the FIGS. 2a and 2b arrangement) presents electrode portions 440, 442 on upper surface 452 of device 450 while the end portion 454 of the device 450 has exposed thereon the end portions of all the electrode layers 120′-128′, representatively illustrated as electrode ends 444, 446. Again it should be appreciated that end portion 456 of device 450 has similarly exposed electrode portions that are not visible in FIG. 4c.

Following an initial firing, termination material 460, 462, 464 is applied to the exposed areas 440, 442 of the top layer 128′ and contacts the remaining electrode ends for each layer 120′-126′ along the end portion 454 by way of termination portion 464. It should be understood that termination portions 462 and 464 continuously cover the top most electrode 128′ portion 442 as well as the electrode portions exposed at end 454 of device 450. It should further be appreciated that similar coverage of exposed electrode ends at end 456 of device 450 is provided although hidden in the current view of the device 450.

Again, it should be recognized that the termination portions 460 and 462 will add to the thickness of the overall part, so thin film techniques such as plating, evaporation, sputtering, or organo-metallic reduction should preferably be used.

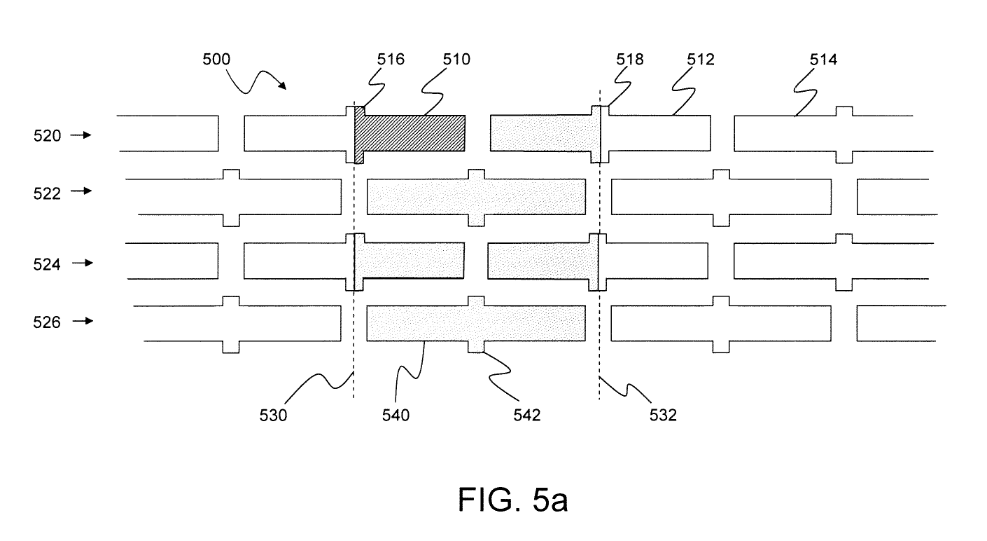

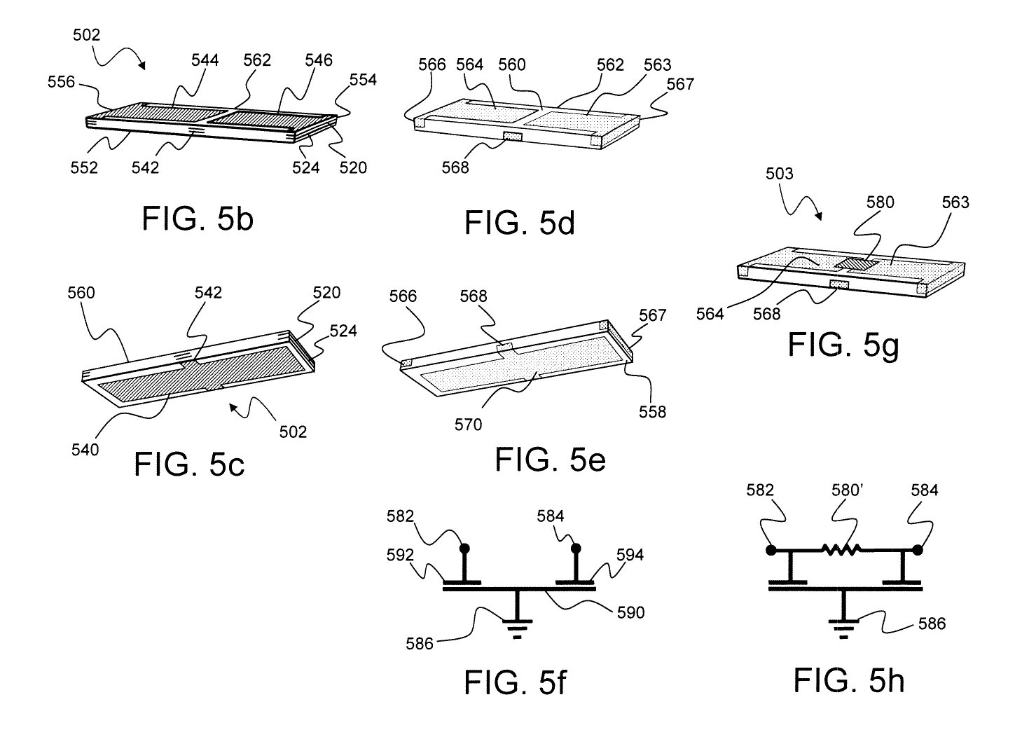

With reference now to FIGS. 5a-5h, a third exemplary embodiment of the present subject matter will now be described. This third exemplary embodiment of the present subject matter again employs a single screen printing mask 500 defined by a plurality of identical printing openings 510, 512, and 514, portions of some of which are again illustrated in shading to more clearly delineate those portions that will correspond to electrode layers. In a manner similar to the previously described second exemplary embodiment, the third exemplary embodiment employs masks 500 that are positioned in only one of two specific locations to produce the desired devices. In this instance, the devices produced have different electrical and physical characteristics than the devices described with respect to the first and second exemplary embodiments in that feedthrough and Pi filter structures may be created, as will be explained further with respect to FIGS. 5f and 5h.

As illustrated in FIG. 5a, in a first lateral position represented by electrode layers 520 and 524, mask 500 is placed such that, upon cutting the resultant prints along cut lines 530, 532 central cross member portions 516 and 518 of mask portions 510 and 512, respectively, are cut at a substantially central portion thereof. In a second lateral position, as illustrated by electrode layers 522 and 526, the electrode layers are positioned such that cutting lines 530, 532 do not intersect with the electrode layers at all but rather actually leave a small gap between the cutting lines and the end of the area defining the electrode. As may be seen from an inspection of FIG. 5a and in a manner similar to FIG. 4b previously discussed, an extension of the cutting process will result in all “good” devices, i.e., none of the devices will be shorted in final production as was the case with the first exemplary embodiment.

A second feature of this embodiment of the present subject matter illustrated in FIG. 5a may be observed by noting that in layers 522 and 526, the central cross member 542 of electrode layer 540, as well as the corresponding electrode in layer 522, is not cut. This uncut cross member, once the various layers are stacked together, becomes a portion of the ground plane connection to the finished device as will be explained further below.

With reference now to FIGS. 5b and 5c, the ground plane connection character of the cross members 542 may be more readily observed. FIGS. 5b and 5c are respectively top and bottom oblique views of the assembled layers of a device 502 constructed in accordance with this exemplary embodiment of the present subject matter. As may be seen in both these Figures, the end of cross member 542 of electrode layer 540 appears at the side edge 552 of partially assembled device 502. It should be appreciated that, although not visible in the present illustrations, similar cross member end elements will appear along side edge 562 of device 502.

Following printing of the various layers 520-528 as represented in FIG. 5a, the cut devices are fired using processes well known to those of ordinary skill in the art, as previously discussed above. This firing process results in a device 502, as illustrated in FIGS. 5b and 5c. As illustrated in FIG. 5b, the top most electrode layer presents electrode portions 544, 546 on upper surface 560 of device 502 while the end portions 554, 556 of the device 502 has exposed thereon the end portions of electrode layers 520 and 524.

Following an initial firing, termination material 563, 464, 566, 567, 568, and 570 (FIG. 5e) is applied to the exposed electrode areas 544, 546 of the top surface 560, and contacts the remaining electrode ends for each layer 520, 524 along the end portion 554, 556, side portions 552, 562 by way of termination portions 568, and bottom portion 558 by way of termination portion 570. It should be understood that termination portions 563 and 564 continuously cover the top most electrode portions 546, 544, respectively, as well as the electrode portions exposed at end 554, 556 of device 502. It should further be appreciated that similar coverage of exposed electrode ends at end 556 of device 502 is provided although hidden in the current view.

It should be understood after contemplation of FIG. 5e, that the termination process is preferably precise. To such end, a self-determining termination process as described in U.S. Pat. No. 6,972,942 (Ritter et al.) could be used.

Following application of the termination material as just outlined, device 502 may be represented by the electrical equivalent circuit diagram of FIG. 5f. As illustrated therein, device 502 may be represented as a pair of capacitors having a common ground electrode 590 that may be connected representatively to a ground terminal 586 that electrically corresponds to termination material 568 and 570 illustrated in FIG. 5e. In similar fashion, a first capacitor plate 592 is illustratively connected to terminal 582 corresponding electrically to termination material 564 and 566 while second capacitor plate 594 is illustratively connected to terminal 584 corresponding electrically to termination material 563 and 567.

Further with respect to this embodiment of the present subject matter, a Pi-filter may be formed using device 503 as illustrated in FIGS. 5g and 5h. With reference now to FIG. 5g, device 503 as illustrated substantially corresponds to the equivalent diagram previously presented in FIG. 5f (referencing device 502) except for the addition of a resistive material patch 580 bridging an end portion of each of electrode termination material layers 563 and 564. The addition of resistive material patch 580 converts the device of FIGS. 5d-5f into a Pi-filter as illustrated in FIG. 5h, wherein resistor 580′ corresponds to a resistor formed by the addition of the resistive material patch 580.

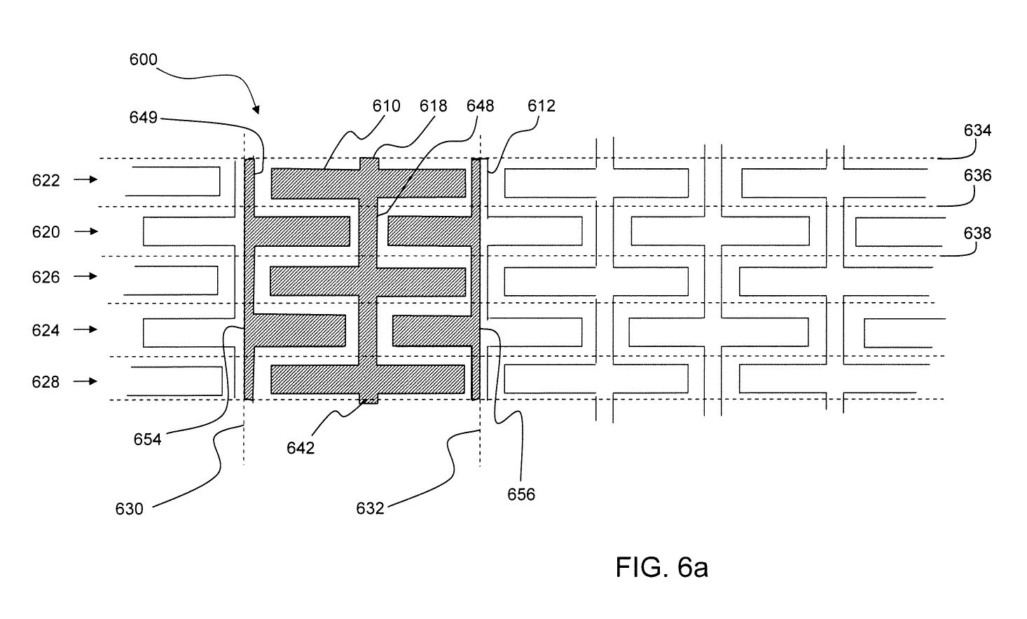

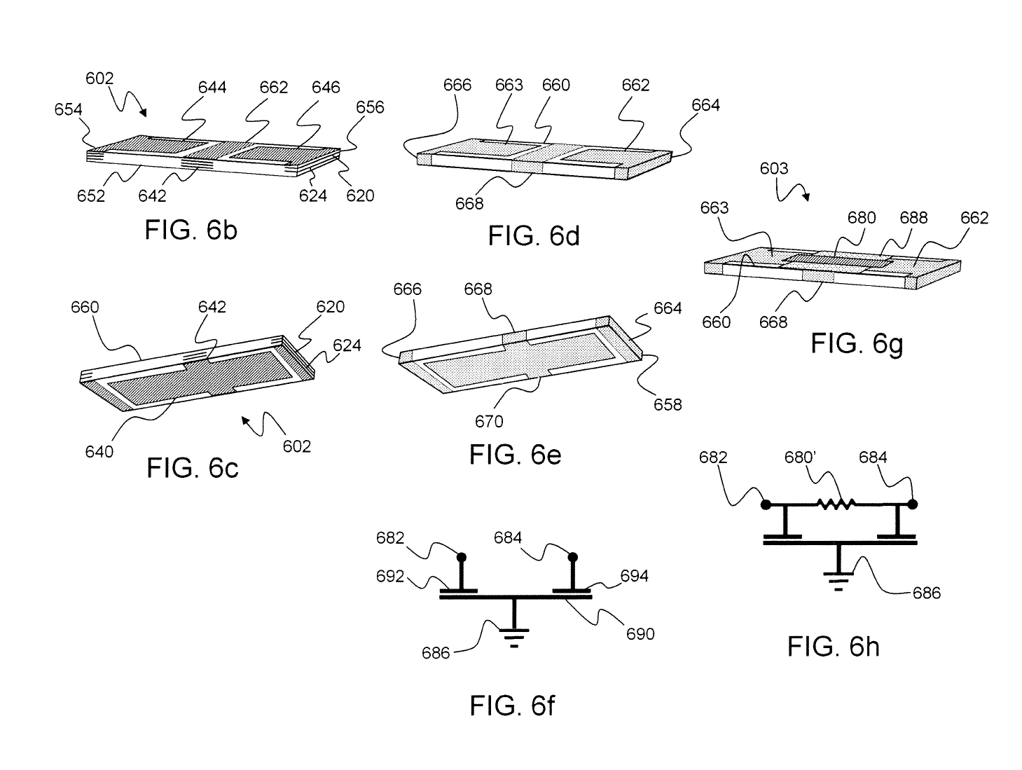

With reference now to FIGS. 6a-6h, a fourth exemplary embodiment of the present subject matter will now be described. This fourth exemplary embodiment of the present subject matter again employs a single screen printing mask 600 defined by a plurality of identical printing openings 610, 612, portions of some of which are again illustrated in shading to more clearly delineate those portions that will correspond to electrode layers. In a manner similar to the previously described second exemplary embodiment, the fourth exemplary embodiment employs masks 600 that are positioned in only one of two specific locations to produce the desired devices. The two mask positions in this embodiment are, however, somewhat different from previously discussed embodiments in that the two mask positions are reached by translation of the mask in both a lateral and vertical direction.

In this instance, the devices produced have different electrical and physical characteristics than the devices described with respect to the first and second exemplary embodiments in that, as with the third exemplary embodiment feedthrough and Pi filter structures may be created as will be explained further with respect to FIGS. 6f and 6h, but also, additional conductive elements are simultaneously produced that provide additional advantageous structural features in the finished form of the device.

As illustrated in FIG. 6a, in a first position represented by electrode layers 620 and 624, mask 600 is positioned such that, upon cutting along cut lines 630, 632 the central cross member portions 618 of mask portion 610 is cut at a substantially central portion thereof. In a second position as illustrated by electrode layers 622, 626 and 628, the electrode layers defined by mask area 610 are positioned such that cutting lines 630, 632 do not intersect with the cross member portions 618 at all but rather actually leave a small gap between the cutting lines and the end of the mask area defining the electrode.

On the other hand, cutting lines 630, 632 do cut portions 618 of adjacently positioned mask positions so that electrode portions bounded by cut lines 630, 634 and 636 will produce a conductive layer at layers 622, 626, and 628 that provides a small conductive area 649 at each end of electrode layers 622, 626, 628 that is not connected to the main electrode portion. Conductive area 649 assists in providing anchoring points for the termination material that will later be applied to the device. In like manner, cutting lines 632, 636, and 638 produce in electrode layers 620 and 624 a “T” shaped electrode portion 644 (FIG. 6b) wherein the top of the “T” shaped portion of the electrode 644 will, when the various electrode layers are stacked together, cooperate with the previously mentioned conductive area 649 to function as anchoring points for termination materials in addition to providing connection points for alternate electrode layers as will be more fully described below.

With further reference to FIG. 6a, it will be noted that layers 620 and 624, when cut by cutting lines 636, 638 produce an electrode layer with “T” shaped electrodes 644, 646 with the top portion of the “T” shape at what will become the end portions 654, 656 (FIG. 6b), respectively, of the device 602. Importantly, in addition to these “T” shaped electrodes 644, 646, a centrally positioned conductive area 648 is produced that, with its end portions 642 (FIG. 6b) from other layers and conductive layer 640 (FIG. 6c) will assist in providing a ground band completely circling the central portion of the completed device.

As may be seen from an inspection of FIG. 6a and in a manner similar to FIGS. 4b and 5b previously discussed, an extension of the cutting process will result in all “good” devices, i.e., none of the devices will be shorted in final production as was the case with the first exemplary embodiment.

With reference now to FIGS. 6b and 6c, the ground plane connection character of the cross members 642, conductive portion 648 and conductive layer 640 may be more readily observed. FIGS. 6b and 6c are respectively top and bottom oblique views of the assembled layers of a device 602 constructed in accordance with this exemplary embodiment of the present subject matter. As may be seen in both these Figures, the end of cross member 642 of electrode layer 640 appears at the side edge 652 of partially assembled device 602. It should be appreciated that, although not visible in the present illustrations, similar cross member end elements will appear along side edge 662 of device 602.

Following printing of the various layers 620-628 as represented in FIG. 6a, the cut devices and stacked layers are fired using processes well known to those of ordinary skill in the art as previously discussed above. This firing process results in a device 602 as illustrated in FIGS. 6b and 6c. As illustrated in FIG. 6b, the top most electrode layer presents electrode portions 644, 646 on upper surface 660 of device 602 while the end portions 654, 656 of the device 602 has exposed thereon the end portions of electrode layers 620 and 624.

Following an initial firing, termination material 662, 663, 664, 666, 668, and 670 (FIG. 6e) is applied to the exposed electrode areas 644, 646 of the top surface 660 and contacts the remaining electrode ends for each layer 620, 624 along the end portion 654, 656, side portions 652, 662 by way of termination portions 668, and bottom portion 640 by way of termination portion 670. It should be understood that termination portions 662 and 666 continuously cover the top most electrode portions 644, 646, respectively, as well as the electrode portions exposed at end 654, 656 of device 602. It should further be appreciated that similar coverage of exposed electrode ends at end 656 of device 602 is provided although hidden in the current view.

Following application of the termination material as just outlined, device 602 may be represented by the electrical equivalent circuit diagram of FIG. 6f. As illustrated therein, device 602 may be represented as a pair of capacitors having a common ground electrode 690 that may be connected representatively to a ground terminal 686 that electrically corresponds to termination material 668 and 670 illustrated in FIG. 6e. In similar fashion, a first capacitor plate 692 is illustratively connected to terminal 682 corresponding electrically to termination material 663 and 666 while second capacitor plate 694 is illustratively connected to terminal 684 corresponding electrically to termination material 662 and 664.

Further with respect to this embodiment of the present subject matter, a Pi-filter may be formed using device 603 as illustrated in FIGS. 6g and 6h. With reference now to FIG. 6g, device 603 as illustrated substantially corresponds to the equivalent diagram previously presented in FIG. 6f (referencing device 602) except for the addition of a resistive material patch 680 and an insulating layer 688 bridging an end portion of each of electrode termination material layers 662 and 663. The resistive material 680 is in electrical contact with the electrode termination layers 662, 663 while the insulating layer 688 prevents contact with the resistive material 680 and the underlying termination material 668 covering conductive areas 648 and end portions 642. The addition of resistive material patch 680 converts the device of FIGS. 6d-6f into a Pi-filter as illustrated in FIG. 6h wherein resistor 680′ corresponds to a resistor formed by the addition of the resistive material patch 680.

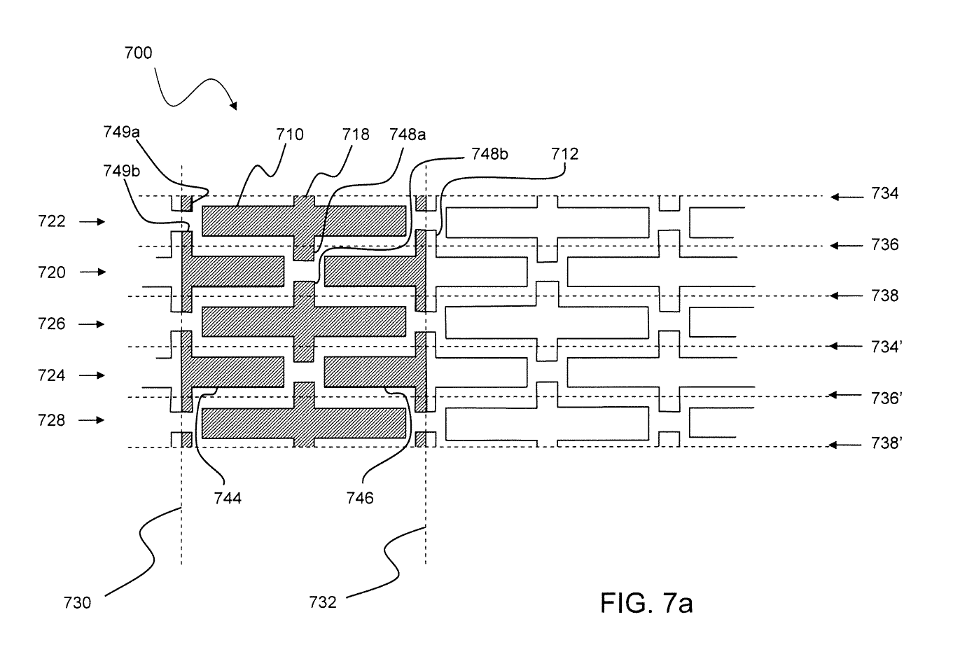

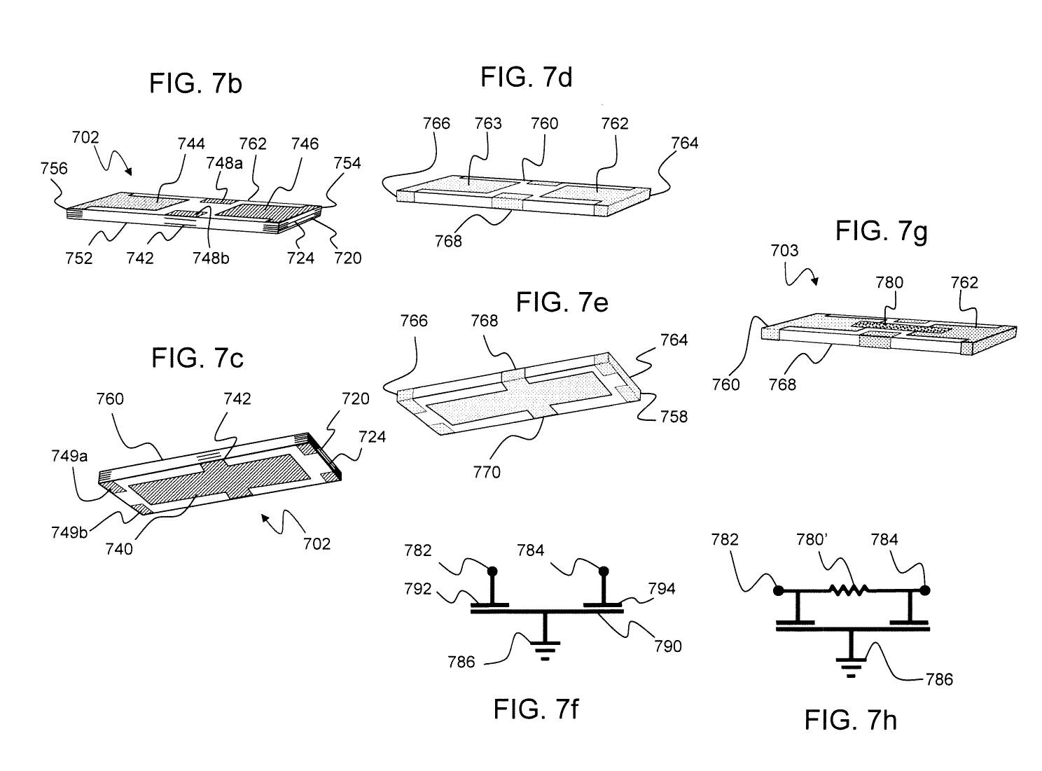

With reference now to FIGS. 7a-7h, a fifth exemplary embodiment of the present subject matter will now be described. This fifth exemplary embodiment of the present subject matter again employs a single screen printing mask 700 defined by a plurality of identical printing openings 710, 712, portions of some of which are again illustrated in shading to more clearly delineate those portions that will correspond to electrode layers. In a manner similar to the previously described fourth exemplary embodiment, the fifth exemplary embodiment employs masks 700 that are positioned in only one of two specific locations to produce the desired devices. The two mask positions in this embodiment are similar to the previously discussed embodiment in that the two mask positions are reached by translation of the mask in both a lateral and vertical direction.

In this instance the devices produced, as with the devices produced in the fourth embodiment, have different electrical and physical characteristics than the devices described with respect to the first and second exemplary embodiments. With this embodiment of the present subject matter feedthrough and Pi filter structures may be created as will be explained further with respect to FIGS. 7f and 7h, but also, additional conductive elements are simultaneously produced that provide additional advantageous structural features in the finished form of the device.

As illustrated in FIG. 7a, in a first position represented by electrode layers 720 and 724, mask 700 is positioned such that, upon cutting along cut lines 730, 732 the central cross member portions 718 of mask portion 710 is cut at a substantially central portion thereof. In a second position as illustrated by electrode layers 722, 726 and 728, the electrode layers defined by mask area 710 are positioned such that cutting lines 730, 732 do not intersect with the cross member portions 718 at all but rather actually leave a small gap between the cutting lines and the end of the mask area defining the electrode.

On the other hand, cutting lines 730, 732 do cut portions 718 of adjacently positioned mask positions so that electrode portions bounded by cut lines 730, 734 and 736 will produce conductive layers at layers 722, 726, and 728 that provide a pair of small conductive area 749a, 749b at each end of electrode layers 722, 726, and 728 that are not connected to the main electrode portion. Conductive areas 749a, 749b assist in providing anchoring points for the termination material that will later be applied to the device as will be described more fully below.

In like manner, cutting lines 730, 736, 734′, 738, and 736′ produce in electrode layers 720 and 724 a “T” shaped electrode portion 744 (FIG. 6b) wherein the top of the “T” shaped portion of the electrode 744 will, when the various electrode layers are stacked together, cooperate with the previously mentioned conductive areas 749a, 749b to function as anchoring points for termination materials in addition to providing connection points for alternate electrode layers as will be more fully described later.

With further reference to FIG. 7a, it will be noted that layers 720 and 724, when cut by cutting lines 730, 732, 736, 738, 734′, and 736′ produce a pair of electrode layers with “T” shaped electrodes 744, 746 with the top portion of the “T” shape at what will become the end portions 754, 756 (FIG. 7b), respectively, of the device 702. Importantly, in addition to these “T” shaped electrodes 744, 746, a pair of centrally positioned conductive areas 748a, 748b are produced that, with its end portions 742 (FIG. 7b) from other layers and conductive layer 740 (FIG. 7c) will assist in providing a ground band partially circling the central portion of the completed device.

As may be seen from an inspection of FIG. 7a and in a manner similar to FIGS. 4b and 5b previously discussed, an extension of the cutting process will result in all “good” devices, i.e., none of the devices will be shorted in final production as was the case with the first exemplary embodiment.

With reference now to FIGS. 7b and 7c, the ground plane connection character of the cross members 742, conductive portions 748a, 748b and conductive layer 740 may be more readily observed. FIGS. 7b and 7c are respectively top and bottom oblique views of the assembled layers of a device 702 constructed in accordance with this exemplary embodiment of the present subject matter. As may be seen in both these Figures, the end of cross member 742 of electrode layer 740 appears at the side edge 752 of partially assembled device 702. It should be appreciated that, although not visible in the present illustrations, similar cross member end elements will appear along side edge 762 of device 702.

Following printing of the various respective layers 720-728 as represented in FIG. 7a, the cut and stacked layers are fired using processes well known to those of ordinary skill in the art as previously discussed above. This firing process results in a device 702 as illustrated in FIGS. 7b and 7c. As illustrated in FIG. 7b, the top most electrode layer presents electrode portions 744, 746 on upper surface 760 of device 702 while the end portions 754, 756 of the device 702 has exposed thereon the end portions of electrode layers 720 and 724.

FIGS. 7d and 7e respectively illustrate in partial side perspective the top and bottom of device 702. Following an initial firing, termination material 762, 763, 764, 766, 768, and 770 (FIG. 7e) is applied to the exposed electrode areas 744, 746 of the top surface 760 and contacts the remaining electrode ends for each layer 720, 724 along the end portion 754, 756, side portions 752, 762 by way of termination portions 768 and bottom portion 740 by way of termination portion 770. It should be understood that termination portions 762 and 766 continuously cover the top most electrode portions 744, 746, respectively, as well as the electrode portions exposed at end 754, 756 of device 702. It should further be appreciated that similar coverage of exposed electrode ends at end 756 of device 702 is provided although hidden in the current view.

Following application of the termination material as just outlined, device 702 may be represented by the electrical equivalent circuit diagram of FIG. 7f. As illustrated therein, device 702 may be represented as a pair of capacitors having a common ground electrode 790 that may be connected representatively to a ground terminal 786 that electrically corresponds to termination material 768 and 770 illustrated in FIG. 7e. In similar fashion, a first capacitor plate 792 is illustratively connected to terminal 782 corresponding electrically to termination material 763 and 766 while second capacitor plate 794 is illustratively connected to terminal 784 corresponding electrically to termination material 762 and 764.

Further with respect to this embodiment of the present subject matter, a Pi-filter may be formed using device 703 as illustrated in FIGS. 7g and 7h. With reference now to FIG. 7g, device 703 as illustrated substantially corresponds to the equivalent diagram previously presented in FIG. 7f (referencing device 702) except for the addition of a resistive material patch 780 bridging an end portion of each of electrode termination material layers 762 and 763. The resistive material 780 is in electrical contact with the electrode termination layers 762, 763 while no insulating layer such as previously used layer 688 (FIG. 6g) is required due to the open space between conductive layers 748a and 748b on top surface 760 of device 702. The addition of resistive material patch 780 converts the device of FIGS. 7d-7f into a Pi-filter as illustrated in FIG. 7h wherein resistor 780′ corresponds to a resistor formed by the addition of the resistive material patch 780.

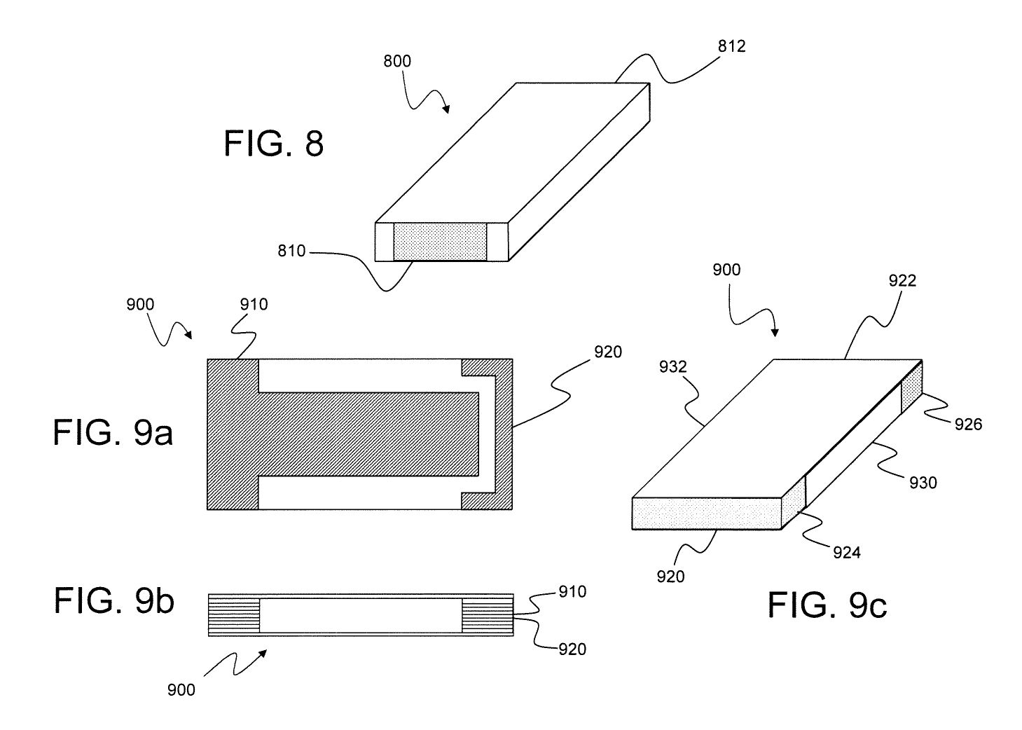

With reference now to FIG. 8, there is illustrated a further exemplary embodiment of a device 800 constructed in accordance with the present subject matter employing end terminations 810. Device 800 may be constructed as illustrated in FIGS. 1a and 1b or, preferably as illustrated in FIGS. 2a-2d, but with the addition of a layer of insulation on the top and bottom surfaces so that end termination 810 may be produced without top terminations such as 160, 162 of FIG. 2d. It should be understood that a termination layer similar to termination layer 810 will be provided on end 812 of device 800.

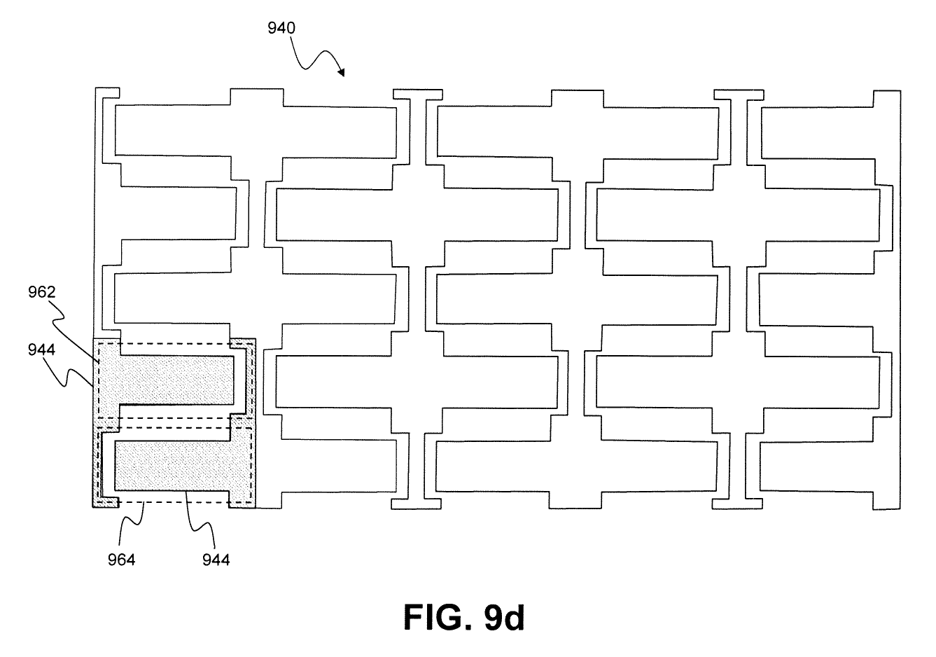

FIGS. 9a-9c illustrate a further exemplary embodiment of an electronic device 900 in accordance with the present subject matter incorporating a “T” electrode and dummy tabs to assist in termination. As may be seen in FIG. 9a, device 900 includes a generally “T” shaped electrode 910 and a generally “U” shaped conductive portion 920. Plural such electrode layers may be provided as illustrated in FIG. 9b with each such layer being reversed from its adjacent such layer. Upon application of termination materials, as illustrated in FIG. 9c, the end portions 920, 922 (termination material hidden in view) and portions 924, 926 of side 930 are covered with termination materials. The “U” shaped conductive portions 920 sandwiched between “T” shaped electrodes 910 function as anchor points for the termination material. It should be understood by those of ordinary skill in the art that there are provided conductive portions on side 932 (not visible in FIG. 9c) of device 900 similar to portions 924, 926 visible in FIG. 9c on side 930 thereof.

FIG. 9d illustrates a single screen pattern for producing electrode layers for the exemplary device 900 illustrated in FIGS. 9a-9c. As with previously illustrated and explained screen patterns, screen pattern subject matter is illustrated with selected portions 942, 944 being shaded, as previously explained, to more clearly indicate the placement of electrode portions within a finished device.

With respect to screen pattern 940, it will be noted that a cutting pattern 962 appears as a dashed line in layer 950 while a similar cutting pattern 964 appears in layer 952. The spacing between those dashed outlines represents the kerf that is removed when one uses a saw to separate the parts. From the present disclosure, it should be evident to those of ordinary skill in the art that, as with previously illustrated and discussed embodiments of the present subject matter, the single printing screen 940 is shifted from side to side between layers to produce the pattern illustrated in FIG. 9d. Moreover, an inspection of the cutting patterns 962, 964 with comparison to the electrode patterns illustrated in FIG. 9b reveals that such cutting patterns provide the illustrated “T” shaped and “U” shaped patterns for alternating device layers.

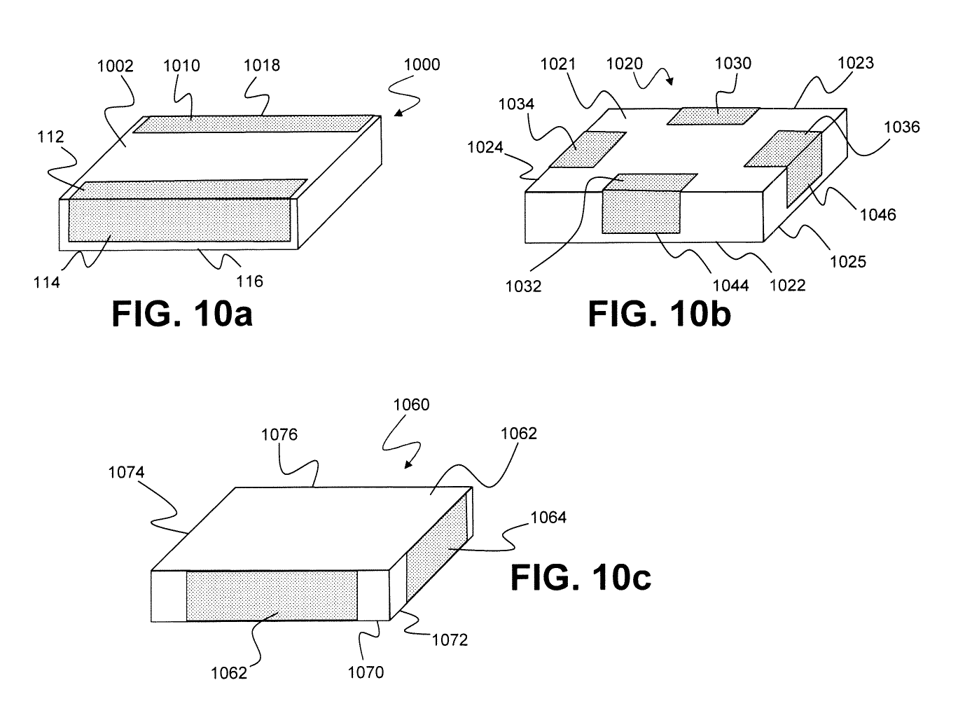

FIGS. 10a-10c illustrate additional exemplary embodiments of electronic devices in accordance with the present subject matter that provides improved mounting ability through 90° symmetry. As illustrated in FIG. 10a, a device 1000 is provided with termination material 1010, 1012 on a top portion 1002 of the device 1000. Termination material 1012 on the top 1002 of device 1000 may be continuously connected to side termination material 1014 on side 1016 of device 1000. In like manner, termination material is provided on side 1018 of device 1000 that, although not visible in FIG. 10a, is continuously connected to termination material 1010 on the top 1002 of device 1000. As may be seen from the two-directional symmetry of device 1000, attention needs to be placed only on mounting in one 90° rotation to assure alignment of the termination material with properly placed trace material on a corresponding circuit board.

FIG. 10b illustrates yet another device 1020 constructed in accordance with the present subject matter and corresponds to a device that may be placed in any 90° orientation. Device 1020 is similar to that illustrated in FIG. 10a except that termination material 1030, 1032, 1034, and 1036 is placed on the top surface 1021 of device 1020 along all four respective sides of the device 1020. In addition, termination material 1044 on side 1022 of device 1020 is continuously coupled to termination material 1032 while termination material 1046 on side 1025 of device 1020 is continuously coupled to termination material 1036 on top 1021 of device 1020. It should be appreciated that side contacting termination material similar to termination material 1044, 1046 on sides 1022, 125, respectively of device 1020 is also supplied on sides 1023, 1024 of device 1020, although not visible in FIG. 10b.

With reference now to FIG. 10c, yet another device 1060 is provided and constructed in accordance with the present subject matter, and provides many of the inherent features of device 1020 illustrated in FIG. 10b. A first similar feature resides in the fact that device 1060 may be mounted in any 90° orientation in a manner similar to device 1020 of FIG. 10b. The principle differences between devices 1060 and 1020 may be readily observed from a comparison of the two Figures (FIGS. 10b and 10c). It will be noted, for example, that no termination material is provided on the top 1062 of device 1060. At the same time termination material is provided more extensively on all four respective sides 1070, 1072, 1074, and 1076 of device 1060 than in device 1020 of FIG. 10b, although only termination material 1062 on side 1070 and 1064 on side 1072 is visible in FIG. 10c.

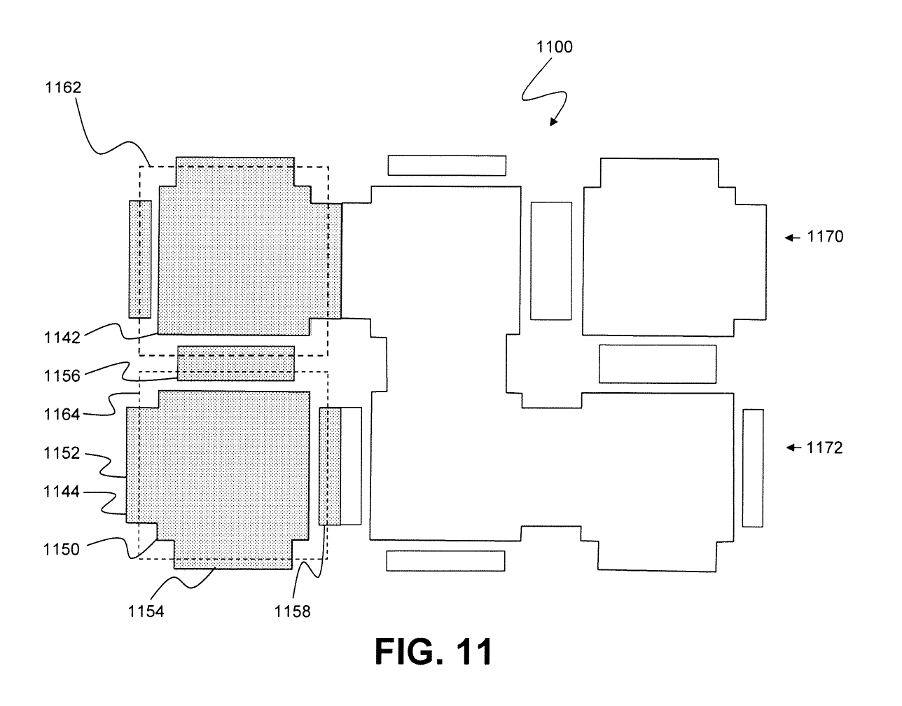

With reference now to FIG. 11 there is illustrated a single screen pattern 1100 for producing electrode layers for the exemplary embodiment illustrated in FIG. 10c. The screen pattern 1100 is somewhat similar to that of FIG. 9d in that the electrode patterns printed in layer 1170 are identical to those of layer 1172 except that they are laterally offset from each other. Again in a manner similar to that of FIG. 9d, cutting patterns 1162, 1164 are followed to produce electrode configurations that, when stacked provides in each layer a main electrode portion 1150 containing two tab portions 1152, 1154 and two unattached conductive portions 1156, 1158 that, in a manner similar to the “U” shaped portions 920 of device 900 (FIG. 9b), provide anchor points for the termination material along the side portions of the finished devices.

It will be further noted that tab portion 1152 is diametrically opposite to unattached conductive portions 1158 while tab portion 1154 is diametrically opposite to unattached conductive portions 1156. This same arrangement, except 90° out of phase, may be seen in layer 1170 so that when multiple layers 1170, 1172 are stacked to produce device 1060, alternate tabs and unattached conductive portions appear in each layer regardless of device orientation. This results in a device 1160 that may be placed on a circuit board in any 90° orientation. In fact, the device 1060 may even be placed upside down and still provide proper conductive paths for associated circuit board connection paths.

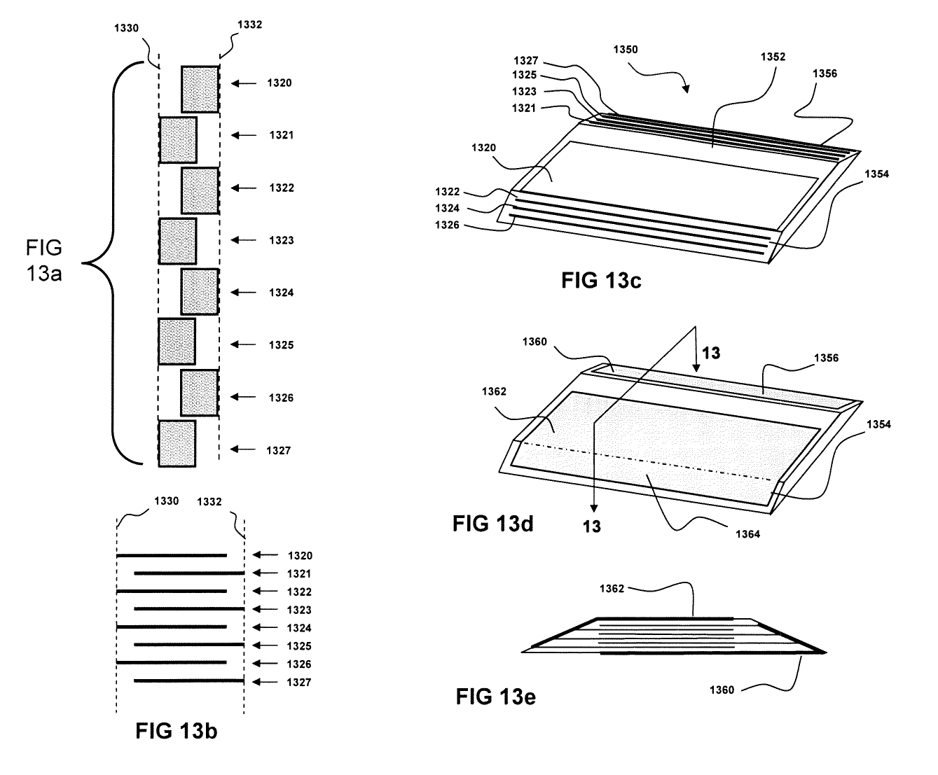

With reference now to FIGS. 13a-13e, there is illustrated yet another exemplary embodiment of the present subject matter. The internal electrode buildup for such embodiment may be similar to that as represented by present FIG. 2a, except that in this instance all the electrode patterns are intended as being identical, such that all of the electrodes are active electrodes. In FIG. 13a, electrodes 1320-1327 are progressively printed and stacked, with the odd numbered electrodes extending to the left edge 1330, and the even numbered electrodes extending to the right edge 1332, as illustrated. A similar arrangement of electrodes is also depicted in FIG. 13b in cross-section.

After stacking and laminating, parts 1350 are diced at an angle on at least two sides, as shown in FIG. 13c in partial perspective. Angle diced edge 1354 now exposes the edges of the even numbered internal electrodes, with electrode 1320 on the top surface 1352. Similarly, angle diced edge 1356 now exposes the odd numbered electrodes, with electrode 1327 on the bottom surface.

Parts 1350 are fired, and then terminated using well known techniques such that surface termination electrode 1362 connects the even numbered electrodes, while termination surface 1360 connects the odd numbered electrodes with a termination surface suitable for bonding.

A more complete understanding of such exemplary structure may be had by reference to FIG. 13e, which represents a cross-section taken along section line 13-13 as illustrated in FIG. 13d. Electrode termination surfaces 1360, 1362 are shown as being in connection with the internal electrodes, and provide multiple connection points to the circuit, either on the edges, or the top and/or bottom.

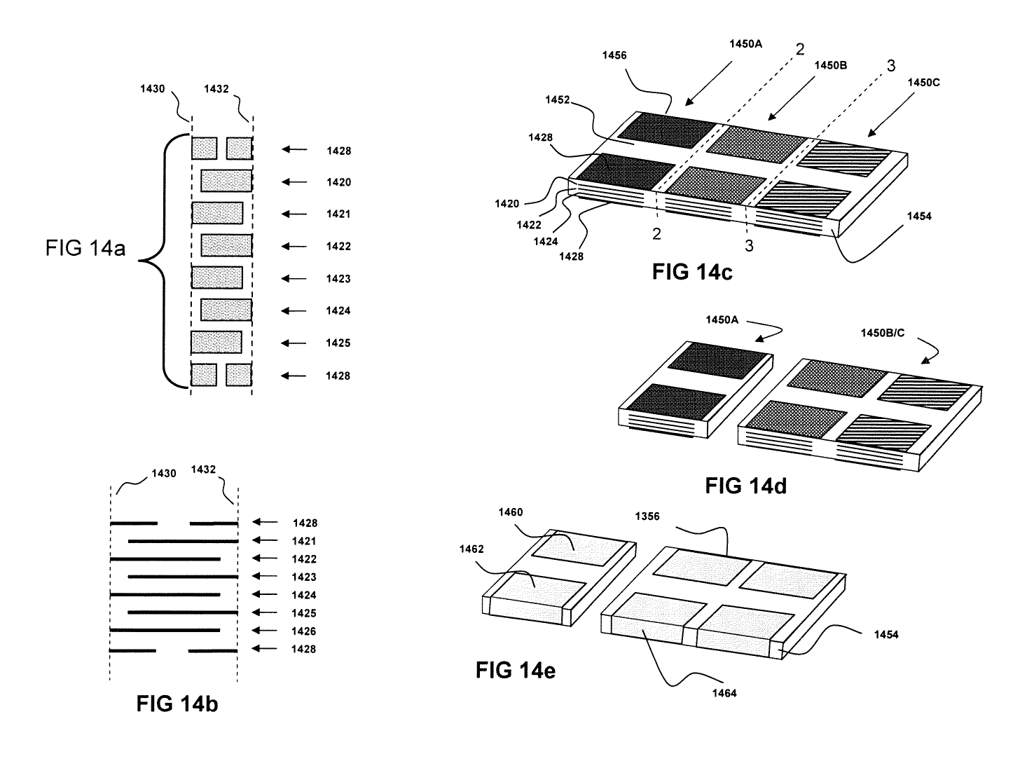

Still another alternative exemplary embodiment of the present subject matter is represented by present FIGS. 14a-14e. Those of ordinary skill in the art will appreciate that components constructed in accordance with the present disclosure are generally made as a part of larger patterns constructed simultaneously with multiple units. The various layers of an array per this exemplary embodiment of the present subject matter are illustrated in FIG. 14a. Layer 1428 corresponds to a cover layer and includes a layer of “dummy tabs” while layers 1420-1425 correspond to active electrodes. “Dummy tabs” correspond to tabs that are provided to assist in the termination process and generally correspond to additional nucleation points for a fine copper termination (FTC) process. When placed on the external surfaces, they also provide bonding pads. A vertically oriented representation of such electrode layers is shown in FIG. 14b, and accordingly reflects reference numbers corresponding to those of FIG. 14a.

FIG. 14c depicts an exemplary array of three parts, 1450A, 1450B, and 1450C. Those of ordinary skill in the art would appreciate that, in production, there may typically be many more parts, generally even several thousand, manufactured together. The portion illustrated in FIG. 14c corresponds to a cover layer of dummy tabs 1428 on surface 1452, illustrated at six locations (although for clarity of illustration representatively designated in only one location). The bottom surface of the array, not shown, may preferably have a similar pattern, and thus the present illustration represents such subject matter as well. Exposed at the same edge surface 1454 are representative electrodes 1420, 1422 and 1424.

Often, per present subject matter, such an array would preferably be cut along cut lines (such as the representative cut lines 2-2 and 3-3 illustrated in exemplary FIG. 14c). However, also per present subject matter, sometimes to achieve a given array implementation, multiple units are kept together, as represented by exemplary FIG. 14d, where one part is singulated (i.e., separated) as 1450A, while exemplary parts 1450B and 1450C are kept contiguous so as to form a two-element array. In many actual practices, it may be more often practiced to have many more elements in an array, the most common being four, but any such specific number is not a limitation of the present disclosure as many more, or, alternatively, fewer elements may be provided, in accordance with the present subject matter.

After separation of the possibly thousands of parts (which were simultaneously or co-extensively created) into individual components or into various plural component arrays as desired for particular purposes or implementations, the respective parts may be terminated using an appropriate plating process to produce the finished parts. Representative finished parts are illustrated in FIG. 14e where illustrated terminations 1460 and 1462 together with the electrically contiguous end portion 1464 permit electrical contact.

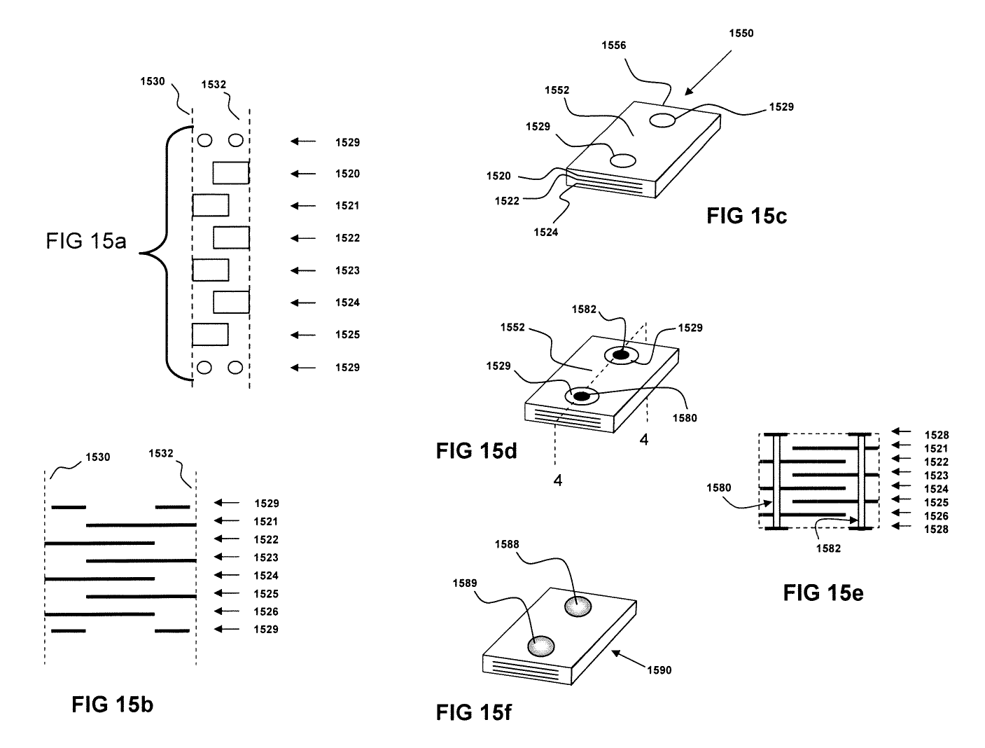

Still another exemplary embodiment of the present subject matter is illustrated in FIGS. 15a-15f. In some instances, it may be preferred to provide a component with a circular or ball mounting configuration as opposed to the tab configurations previously illustrated. For such an exemplary alternative configuration, FIG. 15a shows an exemplary electrode layout, where the cover pattern has been provided for example as a circular pattern represented by elements 1529. The internal electrode layers are similar to previously illustrated and discussed embodiments, and similarly numbered, with 1520, 1522, and 1524 being the right-hand electrodes, and 1521, 1523, and 1525 providing the opposing left-hand ones. The present exemplary alternative embodiment is shown in cross-section in FIG. 15b with identical feature numbers as shown in FIG. 15a. After being stacked, laminated, and diced, the component appears as illustrated in perspective in FIG. 15c, such that the exemplary circular electrodes 1529 appear on the top surface 1552. While only two ball features are shown, it will be appreciated that, if a ball option is used, oftentimes at least three, and sometimes more balls are desired for physical stability during the mounting process, and to reduce the resistance and inductance of the connections. However, if the product is to be just wire bonding pads, for example, two are typically sufficient.

While still green (that is, unfired), vias 1580 and 1582 (see present FIGS. 15d, 15e) may be drilled or punched in the center of circular electrodes 1529, and filled with a conductive material similar to the electrode printing media. A cross-section taken along section line 4-4 as illustrated in present FIG. 15d is represented by FIG. 15e. The part is then fired, and can be plated to provide a solderable or wire-bondable contact surface at 1588 and 1589 to provide the finished part, generally 1590. Alternatively, solder balls may be attached at such sites.

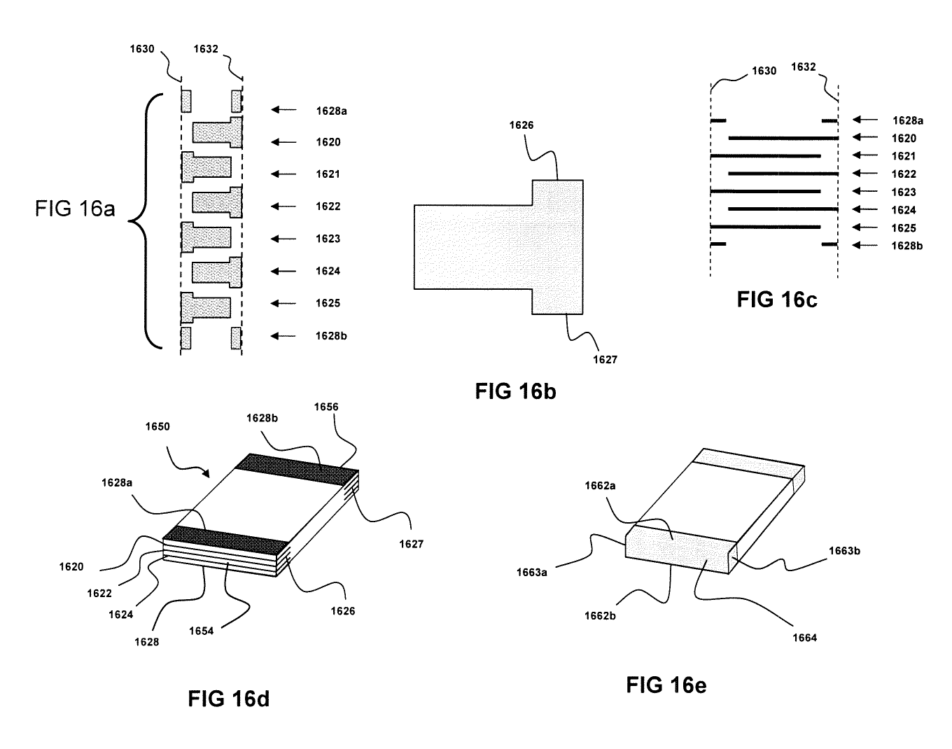

In certain instances or implementations, a desired or preferred mounting method may result in the terminations being five-sided so as to match current state-of-the-art MLC capacitors. In such instances, an electrode design in accordance with the present technology as illustrated in FIG. 16a may be employed. Dummy electrodes 1628a, 1628b at both ends of the layout, will form the top and bottom lands of the final capacitor. In accordance with the present disclosure, a five-sided capacitor may be defined by stacking the generally T-shaped patterns 1620, 1621,1622,1623,1624, and 1625 inside the part, between the dummy electrodes 1628a, 1628b. The even numbered internal electrode patterns 1620, 1622, 1624 are lined up on the right side, 1632 while the odd numbered internal electrode patterns 1621, 1623, 1625 line up on the left side 1630. FIG. 16b shows the detail of such exemplary internal electrodes, emphasizing the tabs 1626 and 1627. An assembled stack of such present exemplary features is represented in a vertical format in FIG. 16c, with the same reference characters common from FIG. 16a.

When the layers are stacked, laminated, and diced, a structure as represented by FIG. 16d is created, with the even numbered electrodes 1620, 1622 and 1624 exposed at the front surface 1654 and the odd numbered electrodes at the back surface 1656 (not visible in such illustration but otherwise represented by such figure). Dummy electrodes 1628a are similarly lined up with front edge 1654 and extend partly over the top and bottom surfaces to be coincident with the side tabs, generally 1626. In like manner, dummy tabs 1628b at the rear line up with the exposed tabs 1627 of the odd numbered electrodes on the side.

When the termination area is plated, an exemplary structure as represented by FIG. 16e is produced, allowing the part to be surface mounted using reflow techniques known in the art without requiring further discussion. The total termination surface in such exemplary arrangement per present subject matter would include 1662a on the top, 1662b on the bottom, 1663a on the left front side, 1663b on the right front side, and 1664 on the front end, with a similar structure provided on the back surface of the completed structure.

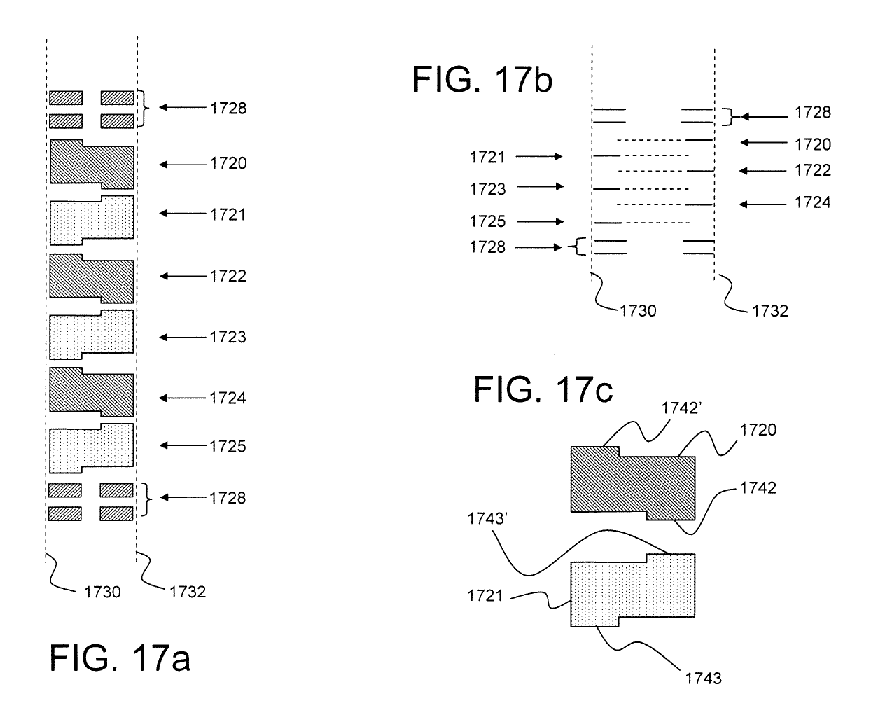

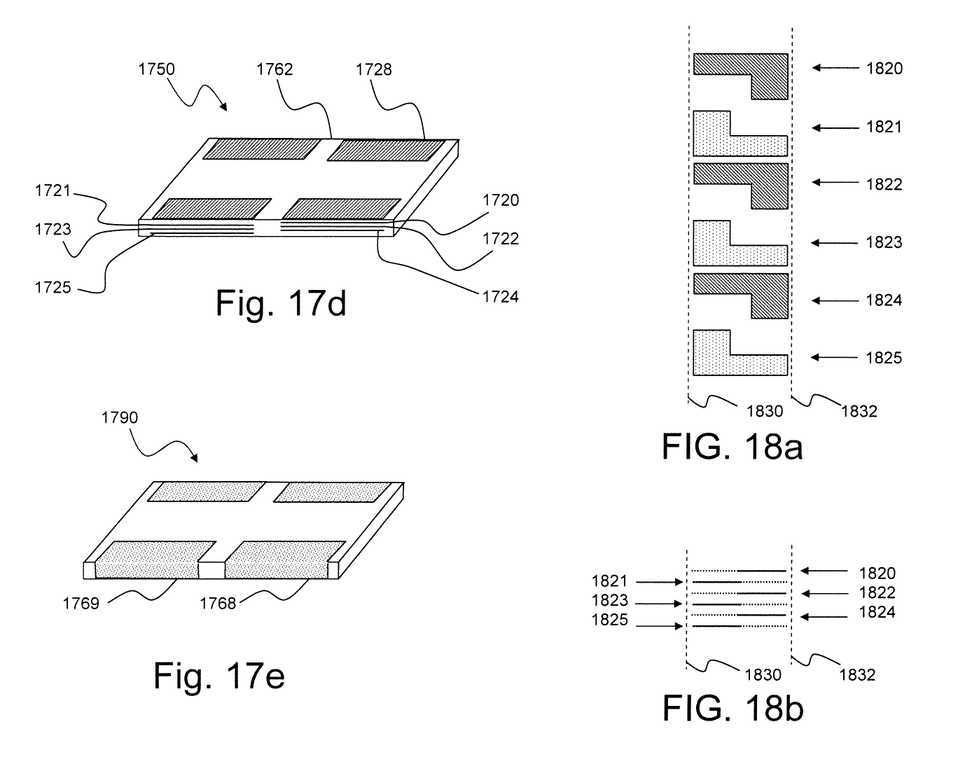

Yet another embodiment of the present subject matter is illustrated in respective FIGS. 17a-17e. The illustrated embodiment has characteristics that advantageously provide for reduced inductance. Reduced inductance may be provided by providing tabs of opposite polarity to provide a cancellation of parasitic inductance effects. More particularly as illustrated in FIG. 17c, electrodes 1720, 1721 may each be provided with tabs 1742, 1742′, and 1743, 1743′, respectively, such that when multiple alternating layers 1720-1725 are stacked as represented in FIGS. 17a and 17b, opposite polarity tabs are produced.

More particularly, FIG. 17a illustrates an electrode stacking sequence where dummy electrodes 1728 provide surface features that will permit wrap-around termination. Exemplary present electrode designs, such as shown in detail in FIG. 17c, alternate polarity as the stack is assembled so that electrodes 1720, 1722, and 1724 are interleaved with layers 1721, 1723 and 1725.

Reference characters 1730 and 1732 depict exemplary cut lines similar to those previously illustrated, for example, at 180, 182 in FIG. 1a. In this instance, the electrode patterns are not intersected by the cut lines. Therefore, no side exposure of the electrodes results.

FIG. 17b shows a cross-section taken through the tabs. The odd-numbered electrode 1721, 1723, and 1725 exit on the left of the illustration while the even numbered 1720, 1722 and 1724 exit on the right of the illustration. Electrodes 1720-1725 correspond to active electrodes and provide overlapping active areas. Surface dummy tabs 1728 do not contribute to the active area of the capacitor but instead are used for termination purposes, as will be further discussed herein below.

FIG. 17c shows a larger detail of exemplary active electrodes 1720 and 1721. Each such electrode 1720, 1721 includes tabs 1742, 1742′ and 1743, 1743′, respectively. Such electrode pairs represent the identically formed odd and even numbered sets of electrodes.

After sufficient and/or desired numbers of layers of alternating electrodes have been stacked, a substantially completed low inductance capacitor generally 1750 is produced as depicted in FIG. 17d. Tabs for electrodes 1720-1725 now exit both designated front side 1752 and designated reverse side 1762. With such tabs, electrodes 1720-1725 form interfaces with the surface dummy tabs 1728 on both top and bottom surfaces. It should be clearly understood and will be appreciated by those of ordinary skill in the art that many more than the exemplary six active electrode layers presently illustrated may be provided in a given capacitor produced in accordance with the present subject matter. Generally, the number of electrode layers may number in the hundreds or more and may be alternately stacked or associated in the manner illustrated until a desired capacitance value is achieved.

Following firing of the stacked and/or associated layers of electrodes by means and/or techniques well known to those of ordinary skill in the art, the component interim product may be terminated, resulting in component generally 1790 as illustrated in FIG. 17e. Terminations 1768 and 1769 connect the electrode tabs and the surface dummy layers in a continuous surface, physically and electrically uniting the termination with the internal electrodes. It is to be understood that such FIG. 17e represents a similar structure which may exist per present subject matter on the back side of such component, though such is not otherwise directly visible in the present illustration.

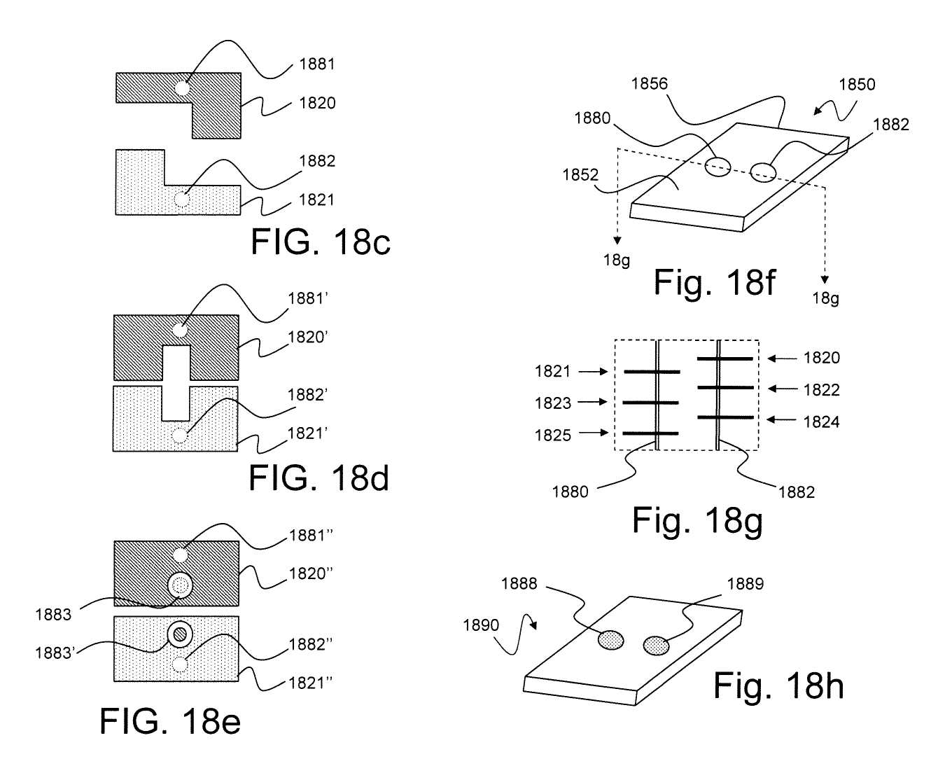

Illustrated by respective FIGS. 18a-18h is yet another embodiment of the present subject matter, and which exemplary embodiment is configured to produce a low inductance capacitor. In such exemplary embodiment, no external tabs or exposed electrodes are provided but instead all connections are advantageously made through a surface via which connects the internal electrodes. FIGS. 18a and 18b illustrate plan and cross section views, respectively, of an exemplary electrode stacking or associating sequence, with electrodes 1820, 1822, and 1824 acting as one polarity, interleaved with electrodes 1821, 1823, and 1825 acting as the opposite polarity. Representative cut lines 1830 and 1832 are situated apart from the edges of the electrode pattern (as in the previous exemplary embodiment) so that no exposed electrodes or tabs are produced.

FIGS. 18c, 18d, and 18e respectively illustrate details of various electrode designs that may be used to accomplish similar purposes. Electrodes 1820, 1820′, and 1820″ illustrated respectively in FIGS. 18c, 18d, and 18e are electrodes of a first polarity, while electrodes 1821, 1821′, and 1821″ are illustrated of the opposite polarity. Each of the electrodes depicted respectively at 1881, 1881′, and 1881″ in one set of electrodes, and 1882, 1882′, and 1882″ in the second set of electrodes, is situated at a location such that a via is intended to pass through the respective electrodes at a later stage in the assembly sequence. In the case of the structure represented by exemplary present FIG. 18e, a “keep-out” area 1883 is designated where conductive electrode material is to be barred so that the finished device will not be shorted out.

FIG. 18b represents a cross section of such exemplary embodiment with the various electrodes properly stacked or assembled. It should be appreciated that there are no tabs extending to the cut lines 1830 and 1832 as in previous embodiments. Electrode sets 1820-1825 are respectively illustrated as they would appear in a transverse cross-section through the middle of the device, showing tab-like portions thereof in solid line illustration, and overlap areas thereof in dotted line illustration.

The assembled device generally 1850 is illustrated in perspective in FIG. 18f. At such point of production, via holes 1880, 1882 have been drilled or punched through the device. The via holes 1880, 1882 are filled with a metal paste, similar to that forming the internal electrodes. The top surface 1852 and the edges 1856 are free of features except for the filled vias.

FIG. 18g illustrates a cross-section taken along section line 18g-18g of FIG. 18f, and illustrates the relation of vias 1880, 1882 to internal electrodes 1820-1825, respectively.

After firing, device 1890 appears as illustrated in FIG. 18h. Solder balls 1888, 1889 may be mounted on the via surface to assist in subsequent electrical connections.

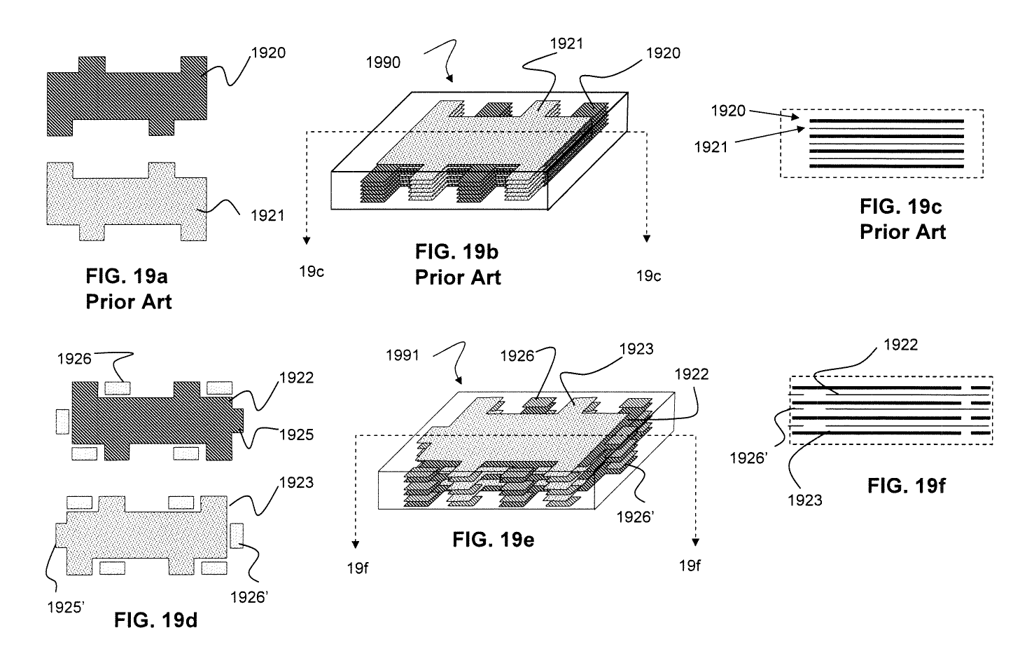

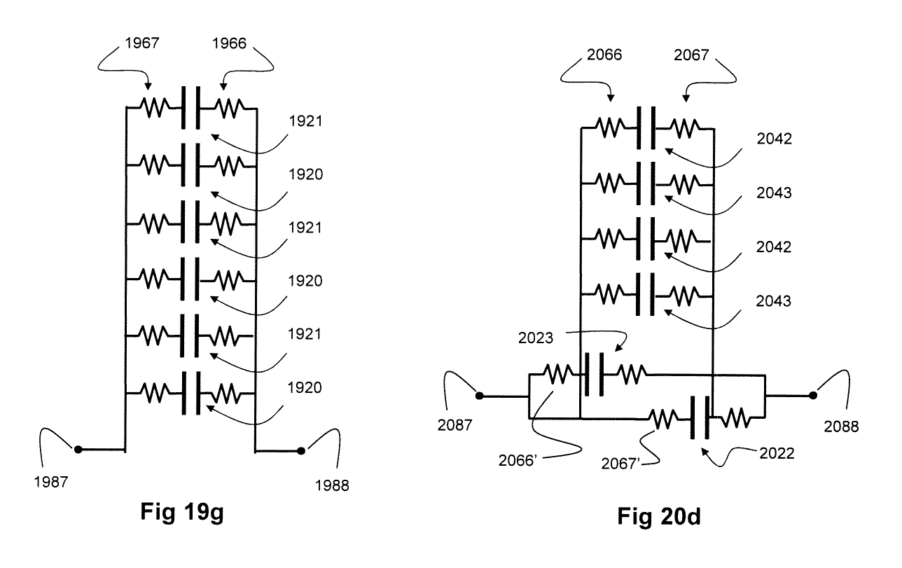

For some applications, low inductance versions of a capacitor are desired or preferred. FIGS. 19a through 19c, respectively, show a low inductance version useful in many instances, using interdigitated electrodes to accomplish such low inductance, generally as described in U.S. Pat. Nos. 5,880,925 (DuPré et al.) and 6,243,253 B1 (DuPré et al.).

FIG. 19a illustrates the two versions of interdigitated electrodes 1920 and 1921 as used in such instance. Such electrodes initially are printed on green ceramic, and stacked with multiple layers, similar to the illustration as shown in exemplary FIG. 19b. FIG. 19b depicts a generally top and side perspective view of such a nearly completed exemplary device 1990, without termination. FIG. 19c illustrates a cross-section of exemplary device 1990 as taken along the section line 19c-19c illustrated in present FIG. 19b. Different electrode polarities are represented by different weight lines.

FIG. 19d illustrates a structure which is similar in some respects but more advanced in other respects. In a fashion similar to structure as described in Ritter et al. U.S. Pat. No. 7,152,291, dummy tabs 1926 and 1926′ provide support and nucleation points for electroless copper termination. Electrodes 1922 and 1923 are similar in some respects to electrodes 1920 and 1921 of present FIG. 19a, except they are provided with end tabs 1925 and 1925′. The function of such tabs, as described in DuPré et al. U.S. Pat. No. 5,880,925 is to reduce inductance and resistance, and to provide for ease of testing during the manufacturing process.

In a manner similar in some respects to that as described above, patterned electrode layers are stacked vertically as shown in FIG. 19e, to provide a device 1991. FIG. 19f illustrates a cross-sectional view of the subject matter of FIG. 19e, taken along section line 19f-19f thereof. Again, different polarity electrodes 1922 and 1923 are shown as different weight lines, with the tabs 1926 and 1926′ shown along the ends to provide anchor points for subsequent termination.

While such designs are useful for their intended purposes, it has been presently determined that there is a potential drawback of such designs in some instances. Such drawback can occur due to the circumstance that the relatively large number of parallel electrodes and their associated parallel resistors combine to provide a very low resistance. In some instances, undesirable effects have been observed in the final circuits in which they are used, including mismatching of impedances, and including a phenomenon known as “ringing”.

As represented in present FIG. 19g (representing in certain respects both exemplary devices 1990 and 1991, the electrode tab structure and the electrode itself provide some resistance. A typical value might be about one ohm. As represented in present FIG. 19g, such resistances 1966 as shown as associated with the first polarity electrodes 1920, with resistor (resistances) 1967 associated with the second polarity (which is impressed on the electrodes 1921).

In a typical capacitor, many layers (sometimes hundreds) are involved. For simplicity and for ease of illustration, the following considers an exemplary set of 6 electrode-resistor sets in parallel. Further for the present example, the total resistance of each capacitor will be regarded as one ohm, and with each capacitance value at one nano-farad. By analytical tools familiar to any one skilled in the art, the capacitances in the configuration of present FIG. 19g will add, for an exemplary total capacitance of six nano-farads. The resistances combine by the well-known reciprocal rule, such that the net resistance is 0.166 ohmns, or 166 milliohms. Such is the resistance that would be measured at terminals 1987 and 1988 of the exemplary configuration of present FIG. 19g. It can be appreciated then, that with capacitors which can have hundreds of layers, the resistance can be very low, such as down to only a few milliohms.

One effort at controlling such parameter is shown in U.S. Pat. No. 7,054,136 (Ritter et al.). Disclosed subject matter in published US Patent Application Publication 2006/0152886 (Togashi et al.) attempts to accomplish such parameter control through the use of vias, but they are expensive to produce and create other electrical problems, such as a propensity for shorting, and a reduction of active electrode areas.

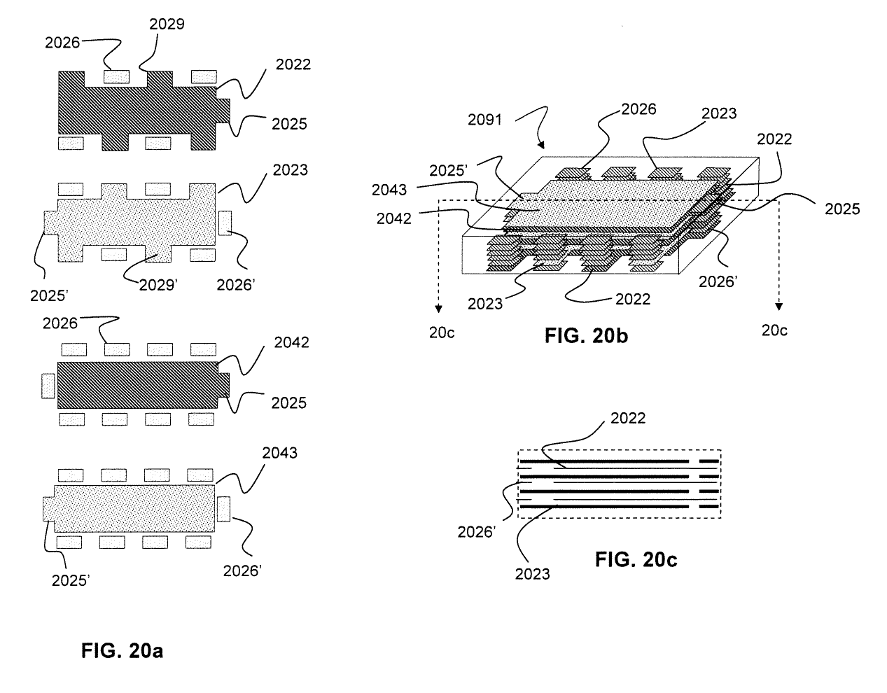

FIGS. 20a through 20d show an improved present device and methodology for effectively controlling such parameters during implementation. Rather than using just two electrode configurations, the present exemplary embodiment of the subject matter of present FIGS. 20a through 20d uses four. As shown in FIG. 20a, the first two electrodes 2022 and 2023 are similar in some respects to the shape of electrodes 1922 and 1923 of the prior art device illustrated in present FIG. 19a. However, after such two electrodes are added multiple layers with the designs of present exemplary electrodes 2042 and 2043. Such electrodes have only one connection to the outside world, which is by way of either end tab 2025 or end tab 2025′. Exemplary dummy tabs 2026 and 2026′ now number nine and by definition, are not connected to the electrode bodies.

Such patterns are stacked as shown in present FIG. 20b, with a cross-section view thereof per present FIG. 20c. Another present aspect of such exemplary embodiment is that the interdigitated electrode tabs 2029 are electrically connected only to the bottom two electrode surfaces. Since the inductance is primarily determined by the closest planes to the circuit board, such device 2091 is still a low inductance capacitor. The rest of the electrode stack (consisting of electrode designs 2042 and 2043) are connected together in parallel but are connected in series to the ends of electrodes 2022 and 2023, respectively.

Various present advantages of such exemplary embodiment are illustrated in conjunction with considering the approximated equivalent circuit of present FIG. 20d. For example, assuming the same exemplary values for resistance and capacitance as in the previous example, the resistance 2066′ associated with electrode 2023 and the resistor (resistance) 2067′ associated with electrode layer 2022 are in parallel. Otherwise, the majority of the electrodes 2042 and 2043 and their resistors 2066 and 2067, respectively, are in parallel with each other, so that the net parameters of the 2042-2043 pair set has a capacitance of 4 nano-farads, and a resistance of 0.25 ohms. The parameters for the 2022-2023 pair set are 2 nano-farads, and 0.5 ohms. Since the capacitances still add, the overall capacitance for the whole device 2091 is 6 nano-farads, but the net resistances for the two parts are 0.5 ohms plus 0.25 ohms (which is 750 milliohms), since they are in series. Such compares with 166 milliohms of the device above, so the benefits of such presently constructed devices may by comparison be appreciated.

Those of ordinary skill in the art will appreciate two important points from the present disclosure. First, as the number of 2042-2043 pair sets gets very much larger, the differences between the net resistances of such construction vis-à-vis the prior art constructions of FIGS. 19a-19c get larger. The second point is that the presently disclosed device can be made symmetrical for mounting purposes by putting a similar pair of electrodes 2022 and 2023 at the upper end of the stack, with only a resulting relatively small sacrifice in resistance increase, especially with many layers.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. Methodology for making multilayer electronic devices, comprising:
providing at least two layers of support material;
providing a single screen printing mask;
placing said mask on a first of the at least two layers of support material;
printing a first conductive pattern on said first layer of the support material through the mask;
placing said mask on a second of the at least two layers of support material;
printing a second conductive pattern on the second layer of the support material; and
combining the first and second layers of support material to produce adjacent printed layers having an upper surface, a lower surface, a front edge, and a back edge.

2. Methodology as in claim 1, wherein said mask is placed on the second layer of support material in a position offset from the position on which the mask is placed on the first layer of support material, so that said combining step produces complimentary electrode layers on adjacent layers of support material.

3. Methodology as in claim 1, wherein providing at least two support layers comprises providing one of at least two dielectric layers, at least two resistive layers, or at least two varistor layers.

4. Methodology as in claim 1, further comprising:
trimming lateral end portions of the combined first and second layers to expose selected conductive patterns; and
applying termination material to at least the trimmed lateral end portions.

5. Methodology as in claim 4, wherein applying termination material comprises applying termination material to at least a portion of selected electrodes exposed on at least one of the upper or lower surfaces of the combined first and second layers.

6. Methodology as in claim 5, further comprising:
firing the combined first and second layers prior to applying termination material.

7. Methodology as in claim 1, further comprising:
placing said mask on a third layer of support material;
printing a third conductive pattern on said third layer of the support material; and
combining such third layer with the first and second layers of support material;
wherein said mask is placed on the third layer of support material in the same position as on the second layer of support material and wherein, upon combining of such third layer with the first and second layers, plural identical electrode layers are produced on adjacent layers of support material in proximity to one of the upper or lower surfaces.

8. Methodology as in claim 1, further comprising:
placing said mask on a third layer of support material;
printing a third conductive pattern on said third layer of support material through the mask;
placing said mask on a fourth layer of support material;
printing a fourth conductive pattern on said fourth layer of the support material;
placing said mask on a fifth layer of support material;
printing a fifth conductive pattern on such fifth layer of the support material;
combining said third, fourth, and fifth layers with the first and second layers of support material one upon the other to produce a combination of printed layers having an upper surface and a lower surface; and
trimming first and second lateral end portions of the combined layers to expose selected conductive patterns;
wherein said mask is placed on the second and fourth layers of support material in a position offset from the position on which said mask is placed on the first, third, and fifth layers of support material; and
wherein, upon trimming of such combined layers, conductive electrode portions are exposed at selected layers and selected lateral end portions.

9. Methodology for producing multilayer electronic devices using a single screen printing mask, comprising:
placing a common mask in alternating positions among plural alternating layers of support material;
screen printing electrode material on the plural alternating layers of support material; and
stacking the plural alternating layers, so that complimentary electrode structure is produced in alternating layers.

10. Methodology as in claim 9, further comprising:
selecting said support material from the group consisting of dielectric material, resistive material, and varistor material.

11. Methodology as in claim 9, further comprising:
trimming lateral end portions of the stacked first and second layers to expose selected conductive patterns; and
applying termination material to at least the trimmed lateral end portions.

12. Methodology as in claim 11, wherein applying termination material comprises applying termination material to at least a portion of selected electrodes exposed on at least one of the upper or lower surfaces of the stacked first and second layers.

13. Methodology as in claim 11, further comprising firing the stacked first and second layers prior to applying termination material.

14. Methodology as in claim 11, wherein said common mask is positioned in alternating positions among said plural alternating layers of support material such that a plurality of parallel connected electronic devices are produced by said applying of termination material.

15. Methodology as in claim 11, wherein said common mask is positioned in alternating positions among said plural alternating layers of support material such that a plurality of series connected electronic devices are produced by said applying of termination material.

16. Methodology as in claim 9, further comprising:
providing said common mask with a central cross member portion, so that said step of placing said common mask in alternating positions among said plural alternating layers of support material produces a central gap in an upper most layer and a central tab portion in a lower most layer, thereby producing a pair of electronic devices having a common electrode.

17. Methodology as in claim 16, wherein said support material comprises a selected dielectric material, so that said pair of electronic devices form a feedthrough capacitor.

18. Methodology as in claim 16, further comprising:
selecting a dielectric material as said support material; and
providing a resistive layer bridging said central gap so that said pair of electronic devices form a Pi filter.

19. Methodology as in claim 16, further comprising:
trimming lateral end and central portions of the stacked first and second layers to expose selected conductive patterns; and
applying termination material to the exposed selected conductive patterns, so that each alternating layer is provided with a T-shaped electrode portion and a U-shaped dummy tab portion.

20. Methodology as in claim 11, wherein:
said trimming includes trimming the lateral end portions at an angle; and
said applying includes applying said termination material to a first trimmed lateral end portion and an upper surface of the device, and separately to a second trimmed lateral end portion and a lower surface of the device.

21. Methodology as in claim 9, further comprising:
providing cover pattern electrode layers as upper most and lower most layers on the stacked plural alternating layers, each cover pattern layer having at least two separate conductive portions.

22. Methodology as in claim 21, further comprising:
trimming lateral end portions of the stacked first, second, and cover layers to expose selected conductive patterns; and
applying termination material to at least the trimmed lateral end portions and cover pattern layers, so that individual upper most and lower most conductive areas are electrically coupled to alternate stacked layers within said device.

23. Methodology as in claim 21, further comprising:
providing at least two vias extending through each of the two separate portions from the upper most to the lower most layers; and
filling said at least two vias with conductive material, so that individual upper most and lower most conductive areas are electrically coupled to alternate stacked layers within said device.

24. Methodology as in claim 23, further comprising using one of plating, evaporation, sputtering, or organo-metallic reduction of selected of said cover pattern electrode layers with a conductive material, so that bondable contact surfaces are provided.

25. Methodology as in claim 23, wherein:
said cover pattern electrode layers are provided as circular patterns; and
wherein said methodology further comprises attaching solder balls to said cover pattern electrodes.

26. Methodology as in claim 23, further comprising providing said common mask as one of a generally L-shaped portion, a generally U-shaped portion, or a rectangular portion.

27. Methodology as in claim 26, further comprising trimming side portions of the stacked first, second, and cover layers so that no conductive patterns are exposed.

28. Methodology as in claim 9, further comprising:
providing at least two opposing ends of said common mask with oppositely extending tab portions extending respectively toward a front and rear portion of the stacked plural alternating layers;
providing cover pattern electrode layers as upper most and lower most layers on the stacked plural alternating layers, each cover pattern layer having at least two separate conductive portions;
trimming lateral end portions of the stacked first, second, and cover layers so that no conductive patterns are exposed;
trimming front and rear portions of the stacked plural alternating layers and cover layers to expose selective portions of said oppositely extending tab portions and cover pattern electrode layers; and
applying terminating material to the exposed tab portions and conductive pattern electrode layers.

29. A multilayer electronic device, comprising:
at least two layers of support material;
a first conductive pattern printed on the first layer of said support material;
a second conductive pattern printed on the second layer of said support material, with said first and second layers of support material combined so as to produce adjacent printed complimentary electrode layers having an upper surface, a lower surface, a front edge, and a back edge, and with lateral end portions of such combined first and second layers trimmed so as to expose selected conductive patterns; and
termination material applied to at least such trimmed lateral end portions.

30. A multilayer electronic device as in claim 29, wherein said device has a minor dimension less than ten mils, and wherein said termination material is less than one mil.

31. A multilayer electronic device as in claim 29, wherein said termination material is one of plated, sputtered, or evaporated onto said trimmed lateral end portions, or situated thereon with organo-metallic reduction.

32. A multilayer electronic device as in claim 29, wherein said device is less than 10 mils thick, and has termination coverage on less than five sides thereof.

33. A multilayer electronic device as in claim 29, wherein said at least two support layers comprise one of at least two dielectric layers, at least two resistive layers, or at least two varistor layers.

34. A multilayer electronic device as in claim 29, further comprising termination material applied to at least a portion of selected electrodes exposed on at least one of the upper or lower surfaces of the combined first and second layers.

35. A multilayer electronic device as in claim 29, further comprising:
a third layer of support material;
a third conductive pattern printed on the third layer of said support material, with said first, second, and third layers of said support material combined so as to produce plural identical electrode layers on adjacent layers of support material in proximity to one of said upper or lower surfaces.

36. A multilayer electronic device as in claim 29, further comprising:
a third layer of support material;
a third conductive pattern printed on the third layer of said support material;
a fourth layer of support material;
a fourth conductive pattern printed on the fourth layer of said support material;
a fifth layer of support material;
a fifth conductive pattern printed on the fifth layer of said support material, with said first, second, third, fourth, and fifth layers of said support material combined so as to produce a combination of printed layers having an upper surface and a lower surface, with lateral end portions of such combined layers trimmed so as to expose selected conductive patterns at selected layers and selected lateral end portions.

37. A multilayer electronic device as in claim 29, wherein said support material comprises material from the group consisting of dielectric material, resistive material, and varistor material.

38. A multilayer electronic device as in claim 29, further comprising a central gap formed in an upper most layer of said layers of support material and a central tab portion in a lower most layer thereof, so as to produce a pair of electronic devices having a common electrode.

39. A multilayer electronic device as in claim 38, wherein said support material comprises a selected dielectric material, so that said pair of electronic devices form a feedthrough capacitor.

40. A multilayer electronic device as in claim 38, further comprising a resistive layer bridging said central gap so that said pair of electronic devices form a Pi filter.

41. A multilayer electronic device as in claim 29, further comprising termination material applied to central portions of said combined first and second layers so as to expose selected conductive patterns, with said termination material providing said device with a T-shaped electrode portion and a U-shaped dummy tab portion.

42. A low inductance controlled equivalent series resistance (ESR) multilayer capacitor, comprising:
at least a first pair of electrodes comprising interdigitated electrodes having a respective end tab on opposite ends thereof, to reduce inductance and resistance, and to provide for ease of testing during the manufacturing process, and having respective side tabs interdigitated with those of the other interdigitated electrode;
at least a second pair of electrodes having a respective end tab on opposite ends thereof, and
dummy tabs formed adjacent said electrodes but not electrically connected thereto, to provide support and nucleation points for electroless copper termination.

43. A low inductance controlled ESR multilayer capacitor as in claim 42, wherein said respective interdigitated side tabs of said first pair of electrodes are electrically connected only to the bottom two electrode surfaces.

44. A low inductance controlled ESR multilayer capacitor as in claim 43, further comprising a second set of said first pair of electrodes, positioned at an upper end of said multilayer device, so as to create a symmetrical device for mounting purposes.

45. A low inductance controlled ESR multilayer capacitor as in claim 43, further comprising additional second pairs of electrodes in stacked patterns, and termination material applied thereto so as to create a circuit of parallel connections of said second pairs of electrodes and series connections thereof with respective opposite ends of said first pair of electrodes.

46. A low inductance controlled ESR multilayer capacitor as in claim 45, wherein said termination material comprises one of plated, sputtered, or evaporated termination material on said trimmed lateral end portions, or situated thereon with organo-metallic reduction.

47. A low inductance controlled ESR multilayer capacitor as in claim 45, wherein said termination material comprises electroless copper terminations.

48. A low inductance controlled equivalent series resistance ESR multilayer capacitor, comprising:
at least a first pair of electrodes comprising interdigitated electrodes having a respective end tab on opposite ends thereof, to reduce inductance and resistance, and to provide for ease of testing during the manufacturing process, and having respective side tabs interdigitated with those of the other interdigitated electrode;
at least a second pair of electrodes having a respective end tab on opposite ends thereof, and termination material selectively interconnecting said electrodes.

49. A low inductance controlled ESR multilayer capacitor as in claim 48, wherein said respective interdigitated side tabs of said first pair of electrodes are electrically connected only to the bottom two electrode surfaces.

50. A low inductance controlled ESR multilayer capacitor as in claim 49, further comprising a second set of said first pair of electrodes, positioned at an upper end of said multilayer device, so as to create a symmetrical device for mounting purposes.

51. A low inductance controlled ESR multilayer capacitor as in claim 49, further comprising additional second pairs of electrodes in stacked patterns, and wherein said termination material is applied so as to create a circuit of parallel connections of said second pairs of electrodes and series connections thereof with respective opposite ends of said first pair of electrodes.

52. A low inductance controlled ESR multilayer capacitor as in claim 51, wherein said termination material comprises one of plated, sputtered, or evaporated termination material on said trimmed lateral end portions, or situated thereon with organo-metallic reduction.

53. A low inductance controlled ESR multilayer capacitor as in claim 51, further including dummy tabs formed adjacent said electrodes but not electrically connected thereto, to provide support and nucleation points for electroless copper termination, and wherein said termination material comprises electroless copper terminations.
